(19) United States
(12) Patent Application Publication
(10) Pub. No.: US 2025/0380553 A1
(43) Pub. Date: Dec. 11, 2025

(54) DISPLAY DEVICE, TILED DISPLAY DEVICE INCLUDING THE SAME, AND AN ELECTRONIC DEVICE INCLUDING THE DISPLAY DEVICE

(71) Applicant: Samsung Display Co., LTD., Yongin-si (KR)

(72) Inventor: Kye Uk LEE, Yongin-si (KR)

(21) Appl. No.: 19/030,645

(22) Filed: Jan. 17, 2025

(30) Foreign Application Priority Data
Jun. 11, 2024 (KR) 10-2024-0075482

(51) Int. Cl. H10H 29/80; H10H 29/24; H10H 29/39

(52) U.S. Cl. CPC H10H 29/842; H10H 29/24; H10H 29/39

(57) ABSTRACT

A display device, a tiled display device including the same, and an electronic device including the display device are provided. The display device including a substrate, a first pad electrode on the substrate, a second pad electrode spaced from the first pad electrode on the substrate, a light emitting element including a first electrode connected to the first pad electrode and a second electrode connected to the second pad electrode, a first power line spaced from the first pad electrode on the substrate, connected to a first side of the second pad electrode, and configured to receive a first source voltage, and a pad light blocking pattern overlapping a first gap between the first pad electrode and the first power line and a second gap between the second pad electrode and the first power line.

### CROSS-REFERENCE TO RELATED APPLICATION

The present application claims priority to and the benefit of Korean Patent Application No. 10-2024-0075482, filed on Jun. 11, 2024, in the Korean Intellectual Property Office, the entire disclosure of which is incorporated by reference herein.

### BACKGROUND

### 1. Field

One or more embodiments of the present disclosure relate to a display device, a tiled display device including the same, and an electronic device including the display device.

### 2. Description of the Related Art

As the information society develops, the demand for display devices for displaying images has increased and diversified. The display devices may be flat panel display devices such as liquid crystal displays (LCDs), field emission displays (FEDs), or light emitting displays (LEDs). A light emitting display device may include an organic light emitting display device including organic light emitting diode (OLED) elements as light emitting elements or a light emitting diode display device including inorganic light emitting diode elements such as light emitting diodes (LEDs) as light emitting elements.

The display device includes a display area where pixels displaying an image are disposed and a non-display area (or a bezel area) which is disposed around the display area and where lines for driving the pixels are disposed. Recently, bezel-less display devices have been released in order to increase an area of the display area as much as possible. Accordingly, the demand for display devices capable of reducing an area of the non-display area or completely eliminating the non-display area by connecting lines disposed on side surfaces and a back surface of a substrate to a circuit board disposed on the back surface of the substrate has increased. However, light directed to the back surface of the substrate from among light of the display area may be reflected from the lines and device identifiers disposed on the back surface of the substrate. Therefore, the lines and device identifiers disposed on the back surface of the substrate may be visually recognized.

### SUMMARY

Aspects and features of embodiments of the present disclosure provide a display device capable of preventing lines and device identifiers disposed on a back surface of a substrate from being viewed.

However, the present disclosure is not limited thereto. The above and other embodiments of the present disclosure will become more apparent to one of ordinary skill in the art to which the present disclosure pertains by referencing the detailed description of the present disclosure given below.

According to one or more embodiments of the present disclosure, there is provided a display device including a substrate, a first pad electrode on the substrate, a second pad electrode spaced from the first pad electrode on the substrate, a light emitting element including a first electrode connected to the first pad electrode and a second electrode connected to the second pad electrode, a first power line spaced from the first pad electrode on the substrate, connected to a first side of the second pad electrode, and configured to receive a first source voltage, and a pad light blocking pattern overlapping a first gap between the first pad electrode and the first power line and a second gap between the second pad electrode and the first power line.

The display device may further include a second power line overlapping a third gap between the first pad electrode and the second pad electrode and configured to receive a second source voltage.

The display device may further include a lower light blocking pattern overlapping the pad light blocking pattern in a thickness direction of the substrate.

An area of the lower light blocking pattern may be greater than an area of the pad light blocking pattern.

A thickness of the lower light blocking pattern may be smaller than a thickness of the pad light blocking pattern.

The pad light blocking pattern may include a first pad light blocking pattern overlapping the first gap, and a second pad light blocking pattern overlapping the second gap and spaced from the first pad light blocking pattern.

The display device may further include a second power line configured to receive a second source voltage.

The second power line overlaps a third gap between the first pad electrode and the second pad electrode.

A minimum distance between the first pad light blocking pattern and the second pad light blocking pattern in one direction may be greater than a length of the third gap in the one direction.

The first pad electrode, the second pad electrode, and the first power line may include a same material.

The second pad electrode and the first power line may be formed integrally with each other.

According to one or more embodiments of the present disclosure, there is provided a display device including a substrate, a first pad electrode on the substrate, a second pad electrode spaced from the first pad electrode on the substrate, a light emitting element including a first electrode connected to the first pad electrode and a second electrode connected to the second pad electrode, a first power line spaced from the first pad electrode on the substrate, connected to a first side of the second pad electrode, and configured to receive a first source voltage, and a lower light blocking pattern overlapping a first gap between the first pad electrode and the first power line and a second gap between the second pad electrode and the first power line.

A thickness of the lower light blocking pattern may be 3,000 Å or more.

The display device may further include an active layer of a thin film transistor on the substrate, a first insulating film on the active layer of the thin film transistor, a gate electrode of the thin film transistor on the first insulating film and overlapping the active layer of the thin film transistor in a thickness direction of the substrate, and a second insulating film on the gate electrode of the thin film transistor.

The lower light blocking pattern may be on the substrate and the active layer of the thin film transistor. The display device may further include a third insulating film between the lower light blocking pattern and the active layer of the thin film transistor.

The first pad electrode and the second pad electrode may be on the second insulating film.

According to one or more embodiments of the present disclosure, there is provided a tiled display device including a plurality of display devices, and a seam portion between the plurality of display devices. A display device from among the plurality of display devices includes a substrate, a first pad electrode on a first surface of the substrate, a second pad electrode spaced from the first pad electrode on the substrate, a light emitting element including a first electrode connected to the first pad electrode and a second electrode connected to the second pad electrode, a first power line spaced from the first pad electrode on the substrate, connected to a first side of the second pad electrode, and configured to receive a first source voltage, and a pad light blocking pattern overlapping a first gap between the first pad electrode and the first power line and a second gap between the second pad electrode and the first power line.

The substrate may include glass.

The display device may further include a side surface line on one side surface between the first surface of the substrate and a second surface opposite to the first surface, a back surface line and a device identifier on the second surface of the substrate, and a flexible film connected to the back surface line through a conductive adhesive member.

The plurality of display devices may be arranged in a matrix form along M rows and N columns.

An electronic device includes a display device, the display device includes: a substrate; a first pad electrode on the substrate; a second pad electrode spaced from the first pad electrode on the substrate; a light emitting element comprising a first electrode connected to the first pad electrode and a second electrode connected to the second pad electrode; a first power line spaced from the first pad electrode on the substrate, connected to a first side of the second pad electrode, and configured to receive a first source voltage; a pad light blocking pattern overlapping a first gap between the first pad electrode and the first power line and a second gap between the second pad electrode and the first power line; and a lower light blocking pattern overlapping the pad light blocking pattern in a thickness direction of the substrate.

The electronic device comprises televisions, laptop computers, monitors, billboards, the Internet of Things (IOT) devices, mobile phones, smartphones, tablet personal computers (PCs), smart watches, watch phones, mobile communication terminals, electronic notebooks, electronic books, portable multimedia players (PMPs), navigation devices, or ultra mobile PCs (UMPCs).

According to the aforementioned and other embodiments of the present disclosure, by disposing a pad light blocking pattern and a first power line so as to overlap a gap formed around pad electrodes, light emitted from a light emitting element is not reflected from lines and a device identifier on a back surface of a display panel through the gap. Therefore, it is possible to improve a phenomenon in which the lines and device identifiers on the back surface of the substrate are visually recognized.

### BRIEF DESCRIPTION OF THE DRAWINGS

The above and other embodiments and features of the present disclosure will become more apparent by describing embodiments thereof with reference to the attached drawings, in which:

FIGS. 1 and 2 are perspective views illustrating a display device according to one or more embodiments;

FIG. 3 is a layout diagram illustrating first to third sub-pixels of a pixel of the display device according to one or more embodiments;

FIG. 4 is a block diagram illustrating the display device according to one or more embodiments;

FIG. 5 is an equivalent circuit diagram illustrating the first sub-pixel according to one or more embodiments;

FIG. 6 is a layout diagram illustrating a first pad electrode, a second pad electrode, a third power line, and a lower light blocking pattern of the first sub-pixel according to one or more embodiments;

FIG. 7 is a cross-sectional view illustrating an example of a display panel taken along the line I1-I1′ of FIG. 6;

FIG. 8 is a layout diagram illustrating a first pad electrode, a second pad electrode, a first power line, a third power line, and a pad light blocking pattern of the first sub-pixel according to one or more embodiments;

FIG. 9 is a cross-sectional view illustrating an example of the display panel taken along the line I2-I2′ of FIG. 8;

FIG. 10 is a cross-sectional view illustrating an example of the display panel taken along the line I3-I3′ of FIG. 8;

FIG. 11 is a cross-sectional view illustrating an example of the display panel taken along the line I4-I4′ of FIG. 8;

FIG. 12 is a layout diagram illustrating a first pad electrode, a second pad electrode, a first power line, a third power line, a first pad light blocking pattern, and a second pad light blocking pattern of the first sub-pixel according to one or more embodiments;

FIG. 13 is a cross-sectional view illustrating an example of the display panel taken along the line I6-I6′ of FIG. 12;

FIG. 14 is a cross-sectional view illustrating an example of the display panel taken along the line I7-I7′ of FIG. 12;

FIG. 15 is a perspective view illustrating a tiled display device including a plurality of display devices according to one or more embodiments;

FIG. 16 is an enlarged layout diagram illustrating an area Y of FIG. 15 in detail; and

FIG. 17 is a cross-sectional view illustrating an example of the tiled display device taken along the line N-N′ of FIG. 16.

### DETAILED DESCRIPTION

Aspects and features of embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, and/or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

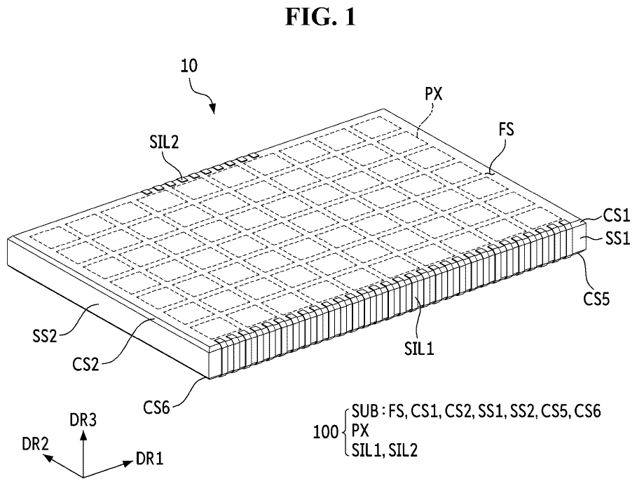

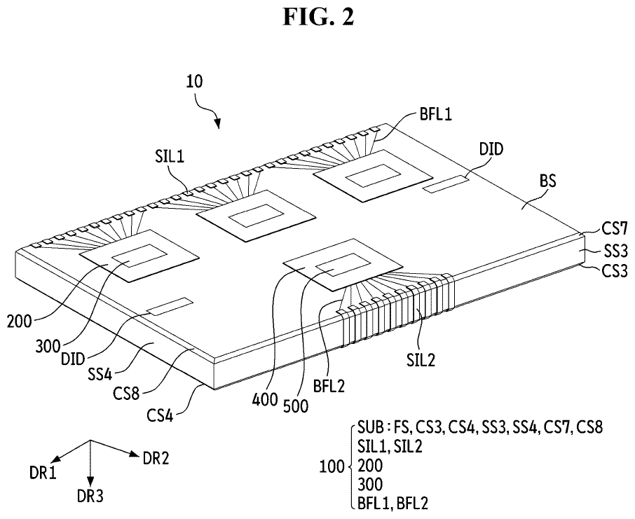

FIGS. 1 and 2 are perspective views illustrating a display device according to one or more embodiments.

Referring to FIGS. 1 and 2, a display device 10 according to one or more embodiments is a device that displays a moving image and/or a still image, and may be used as a display screen of various products such as televisions, laptop computers, monitors, billboards, and/or the Internet of Things (IOT) devices as well as portable electronic devices such as mobile phones, smartphones, tablet personal computers (PCs), smart watches, watch phones, mobile communication terminals, electronic notebooks, electronic books, portable multimedia players (PMPs), navigation devices, and/or ultra mobile PCs (UMPCs).

The display device 10 according to one or more embodiments may include a display panel 100, circuit boards 200, and source drivers 300.

The display panel 100 may include a substrate SUB, first back surface fan-out lines BFL1, second back surface fan-out lines BFL2, a plurality of pixels PX, a plurality of first side surface lines SIL1, a plurality of second side surface lines SIL2, and a plurality of device identifiers DID.

The substrate SUB may include a first surface FS, a second surface BS, a plurality of chamfered surfaces CS1 to CS8, and a plurality of side surfaces SS1 to SS4.

The first surface FS may be a front surface of the substrate SUB. The first surface FS may have a rectangular shape having long sides in a first direction DR1 and short sides in a second direction DR2.

The second surface BS may be a surface facing the first surface FS. The second surface BS may be a back surface of the substrate SUB. The second surface BS may have a rectangular shape having long sides in the first direction DR1 and short sides in the second direction DR2.

The plurality of chamfered surfaces CS1 to CS8 refer to surfaces that are disposed between the first surface FS and the plurality of side surfaces SS1 to SS4 and between the second surface BS and the plurality of side surfaces SS1 to SS4 and are obliquely chamfered, in order to prevent chipping defects from occurring in the plurality of first side surface lines SIL1 and the plurality of second side surface lines SIL2. A bending angle of each of the plurality of first side surface lines SIL1 and the plurality of second side surface lines SIL2 may become gentle due to the plurality of chamfered surfaces CS1 to CS8, and it is thus possible to prevent chipping or cracks from occurring in the plurality of first side surface lines SIL1 and the plurality of second side surface lines SIL2.

A first chamfered surface CS1 may extend from a first side, for example, a lower side, of the first surface FS. A second chamfered surface CS2 may extend from a second side, for example, a left side, of the first surface FS. A third chamfered surface CS3 may extend from a third side, for example, an upper side, of the first surface FS. A fourth chamfered surface CS4 may extend from a fourth side, for example, a right side, of the first surface FS. An internal angle formed by the first surface FS and the first chamfered surface CS1, an internal angle formed by the first surface FS and the second chamfered surface CS2, an internal angle formed by the first surface FS and the third chamfered surface CS3, and an internal angle formed by the first surface FS and the fourth chamfered surface CS4 may be greater than 90°.

A fifth chamfered surface CS5 may extend from a first side, for example, a lower side, of the second surface BS. A sixth chamfered surface CS6 may extend from a second side, for example, a left side, of the second surface BS. A seventh chamfered surface CS7 may extend from a third side, for example, a upper side, of the second surface BS. An eighth chamfered surface CS8 may extend from a fourth side, for example, a right side, of the second surface BS. An internal angle formed by the second surface BS and the fifth chamfered surface CS5, an internal angle formed by the second surface BS and the sixth chamfered surface CS6, an internal angle formed by the second surface BS and the seventh chamfered surface CS7, and an internal angle formed by the second surface BS and the eighth chamfered surface CS8 may be greater than 90°.

A first side surface SS1 may extend from the first chamfered surface CS1. The first chamfered surface CS1 may be disposed between the first surface FS and the first side surface SS1. The first side surface SS1 may be a lower side surface of the substrate SUB.

A second side surface SS2 may extend from the second chamfered surface CS2. The second chamfered surface CS2 may be disposed between the first surface FS and the second side surface SS2. The second side surface SS2 may be a left side surface of the substrate SUB.

A third side surface SS3 may extend from the third chamfered surface CS3. The third chamfered surface CS3 may be disposed between the first surface FS and the third side surface SS3. The third side surface SS3 may be an upper side surface of the substrate SUB.

A fourth side surface SS4 may extend from the fourth chamfered surface CS4. The fourth chamfered surface CS4 may be disposed between the first surface FS and the fourth side surface SS4. The fourth side surface SS4 may be a right side surface of the substrate SUB.

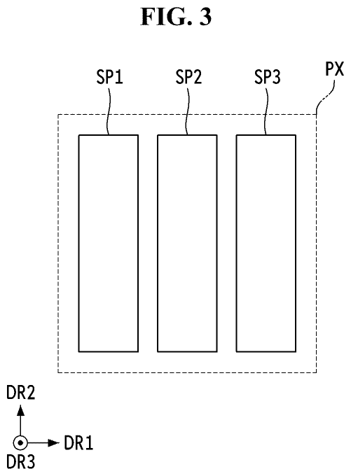

The plurality of pixels PX may be disposed on the first surface FS of the substrate SUB to display an image. The plurality of pixels PX may be arranged in a matrix form ALONG the first direction DR1 and the second direction DR2. The plurality of pixels PX will be described later with reference to FIG. 3.

The plurality of first side surface lines SIL1 may be disposed on the first surface FS, the second surface BS, at least two of the plurality of chamfered surfaces CS1 to CS8, and at least one of the plurality of side surfaces SS1 to SS4. For example, the plurality of first side surface lines SIL1 may be disposed on the first surface FS, the second surface BS, the first chamfered surface CS1, the fifth chamfered surface CS5, and the first side surface SS1 in order to connect first pads disposed on the first side of the first surface FS and the first back surface fan-out lines BFL1 on the second surface BS to each other.

The plurality of second side surface lines SIL2 may be disposed on the first surface FS, the second surface BS, at least two of the plurality of chamfered surfaces CS1 to CS8, and at least one of the plurality of side surfaces SS1 to SS4. For example, the plurality of second side surface lines SIL2 may be disposed on the first surface FS, the second surface BS, the third chamfered surface CS3, the seventh chamfered surface CS7, and the third side surface SS3 in order to connect second pads disposed on the second side of the first surface FS, which is a side opposite to the first side of the first surface FS, and the second back surface fan-out lines BFL2 on the second surface BS to each other.

The plurality of first side surface lines SIL1 serve to connect the first pads disposed on the first surface FS and the first back surface fan-out lines BFL1 disposed on the second surface BS to each other, respectively. The plurality of second side surface lines SIL2 serve to connect the second pads disposed on the first surface FS and the second back surface fan-out lines BFL2 disposed on the second surface BS to each other, respectively. The first pads and the second pads may correspond to front surface pads. The first pads may be connected to data lines connected to the pixels PX of the substrate SUB. Some of the second pads may be connected to a first power line disposed on the first surface FS of the substrate SUB, and others of the second pads may be connected to a global power line disposed on the first surface FS of the substrate SUB.

Each of the plurality of device identifiers DID may be an identifier such as an identification number assigned to each of the display devices 10 in order to distinguish the display devices 10 from each other. The plurality of device identifiers DID may be disposed on the second surface BS of the substrate SUB. The plurality of device identifiers DID may be disposed to be spaced (e.g., spaced apart) from the first back surface fan-out lines BFL1, the second back surface fan-out lines BFL2, the plurality of first side surface lines SIL1, and the plurality of second side surface lines SIL2 in a plan view. In addition, the device identifiers DID may be disposed to be spaced (e.g., spaced apart) from a plurality of first circuit boards 200 and a second circuit board 400 in a plan view. That is, the plurality of device identifiers DID may be in a state in which they are electrically floated.

Some of the plurality of device identifiers DID may be disposed adjacent to the second chamfered surface CS2, and others of the plurality of device identifiers DID may be disposed adjacent to the fourth chamfered surface CS4. Some of the plurality of device identifiers DID may be disposed more adjacent to the first chamfered surface CS1 than others of the plurality of device identifiers DID are. In addition, others of the plurality of device identifiers DID may be disposed more adjacent to the third chamfered surface CS3 than some of the plurality of device identifiers DID are.

The plurality of device identifiers DID may be back surface metal layers formed through the same process as the first back surface fan-out lines BFL1 and the second back surface fan-out lines BFL2 using the same material as the first back surface fan-out lines BFL1 and the second back surface fan-out lines BFL2. For example, the back surface metal layer may be formed as a single layer or multiple layers made of molybdenum (Mo), aluminum (Al), chromium (Cr), gold (Au), titanium (Ti), nickel (Ni), neodymium (Nd), and/or copper (Cu), and/or alloys thereof.

The plurality of first circuit boards 200 may be disposed on the second surface BS of the substrate SUB. The plurality of first circuit boards 200 may be connected to the first back fan-out lines disposed on the second surface BS of the substrate SUB using conductive adhesive members such as anisotropic conductive films, respectively. The plurality of first circuit boards 200 may be electrically connected to the plurality of first side surface lines SIL1 through the first back surface fan-out lines BFL1. Each of the plurality of first circuit boards 200 may be a flexible printed circuit board (FPCB), a printed circuit board (PCB), or a flexible film.

The second circuit board 400 may be disposed on the second surface BS of the substrate SUB. The second circuit board 400 may be connected to the second back surface fan-out lines BFL2 disposed on the second surface BS of the substrate SUB using conductive adhesive members. The second circuit board 400 may be electrically connected to the plurality of second side surface lines SIL2 through the second back surface fan-out lines BFL2. The second circuit board 400 may be a flexible printed circuit board (FPCB), a printed circuit board (PCB), or a flexible film.

Each of the source drivers 300 may generate data voltages and supply the data voltages to the data lines through the first circuit board 200, the first back surface fan-out lines BFL1, and the plurality of first side surface lines SIL1. Each of the source drivers 300 may be formed as an integrated circuit (IC) and attached onto the circuit board 200 corresponding thereto. Alternatively, each of the source drivers 300 may be directly attached to the second surface BS of the substrate SUB in a chip on glass (COG) manner.

A power supply unit 500 may generate voltages (e.g., predetermined voltages) and supply the voltages (e.g., predetermined voltages) to voltage lines (e.g., predetermined voltage lines) through the second circuit board 400, the second back surface fan-out lines BFL2, and the plurality of second side surface lines SIL2. For example, the power supply unit 500 may generate a first source voltage and supply the first source voltage to a first power line through the second circuit board 400, the second back surface fan-out lines BFL2, and the plurality of second side surface lines SIL2. In addition, the power supply unit 500 may generate a global source voltage GV and supply the global source voltage GV to a global power line through the second circuit board 400, the second back surface fan-out lines BFL2, and the plurality of second side surface lines SIL2. The power supply unit 500 may be formed as an integrated circuit (IC) and attached onto the second circuit board 400. Alternatively, the power supply unit 500 may be directly attached to the second surface BS of the substrate SUB in a chip on glass (COG) manner.

As illustrated in FIGS. 1 and 2, by using the plurality of first side surface lines SIL1 and the plurality of second side surface lines SIL2, it is possible to eliminate a flexible film bent along a side surface of the substrate SUB. For this reason, a bezel-less display device may be implemented.

FIG. 3 is a layout diagram illustrating first to third sub-pixels of a pixel according to an one or more embodiments.

Referring to FIG. 3, each of the pixels PX may include a plurality of sub-pixels SP1, SP2, and SP3. It has been illustrated in FIG. 3 that each of the pixels PX includes three sub-pixels SP1, SP2, and SP3, that is, a first sub-pixel SP1, a second sub-pixel SP2, and a third sub-pixel SP3, but the present disclosure is not limited thereto. Each of the first sub-pixel SP1, the second sub-pixel SP2, and the third sub-pixel SP3 may be connected to one of pulse width modulation (PWM) data lines DL, one of first to third data lines RDL, GDL, and BDL, and at least one of scan lines GWL, GIL, GCL, SWPL, PAEL, and PWEL.

Each of the first sub-pixel SP1, the second sub-pixel SP2, and the third sub-pixel SP3 may have a rectangular shape, a square shape, and/or a rhombic shape in a plan view. For example, each of the first sub-pixel SP1, the second sub-pixel SP2, and the third sub-pixel SP3 may have a rectangular shape, in a plan view, having short sides in the first direction DR1 and long sides in the second direction DR2, as illustrated in FIG. 3. Alternatively, each of the first sub-pixel SP1, the second sub-pixel SP2, and the third sub-pixel SP3 may have a square or rhombic shape, in a plan view, including sides having the same length in the first direction DR1 and the second direction DR2.

As illustrated in FIG. 3, the first sub-pixel SP1, the second sub-pixel SP2, and the third sub-pixel SP3 may be arranged along the first direction DR1. Alternatively, any one of the second sub-pixel SP2 and the third sub-pixel SP3 and the first sub-pixel SP1 may be arranged along the first direction DR1, and the other ones of the second sub-pixel SP2 and the third sub-pixel SP3 and the first sub-pixel SP1 may be arranged along the second direction DR2. For example, the first sub-pixel SP1 and the second sub-pixel SP2 may be arranged along the first direction DR1, and the first sub-pixel SP1 and the third sub-pixel SP3 may be arranged along the second direction DR2. Alternatively, one of the first sub-pixel SP1 and the third sub-pixel SP3 and the second sub-pixel SP2 may be arranged along the first direction DR1, and the other one of the first sub-pixel SP1 and the third sub-pixel SP3 and the second sub-pixel SP2 may be arranged along the second direction DR2. Alternatively, one of the first sub-pixel SP1 and the second sub-pixel SP2 and the third sub-pixel SP3 may be arranged along the first direction DR1, and the other one of the first sub-pixel SP1 and the second sub-pixel SP2 and the third sub-pixel SP3 may be arranged along the second direction DR2.

The first sub-pixel SP1 may emit first light, the second sub-pixel SP2 may emit second light, and the third sub-pixel SP3 may emit third light. Here, the first light may be light of a red wavelength band, the second light may be light of a green wavelength band, and the third light may be light of a blue wavelength band. The red wavelength band may be a wavelength band of approximately 600 nm to 750 nm, the green wavelength band may be a wavelength band of approximately 480 nm to 560 nm, and the blue wavelength band may be a wavelength band of approximately 370 nm to 460 nm, but the present disclosure is not limited thereto.

Each of the first sub-pixel SP1, the second sub-pixel SP2, and the third sub-pixel SP3 may include an inorganic light emitting element having an inorganic semiconductor as a light emitting element emitting light. For example, the inorganic light emitting element may be a flip chip-type micro light emitting diode (LED), but the present disclosure is not limited thereto.

As illustrated in FIG. 3, an area of the first sub-pixel SP1, an area of the second sub-pixel SP2, and an area of the third sub-pixel SP3 may be substantially the same as each other, but the present disclosure is not limited thereto. At least one of an area of the first sub-pixel SP1, an area of the second sub-pixel SP2, and an area of the third sub-pixel SP3 may be different from another one of the area of the first sub-pixel SP1, the area of the second sub-pixel SP2, and the area of the third sub-pixel SP3. Alternatively, any two of an area of the first sub-pixel SP1, an area of the second sub-pixel SP2, and an area of the third sub-pixel SP3 may be substantially the same as each other, and the other one of the area of the first sub-pixel SP1, the area of the second sub-pixel SP2, and the area of the third sub-pixel SP3 may be different from the two of the area of the first sub-pixel SP1, the area of the second sub-pixel SP2, and the area of the third sub-pixel SP3. Alternatively, an area of the first sub-pixel SP1, an area of the second sub-pixel SP2, and an area of the third sub-pixel SP3 may be different from each other.

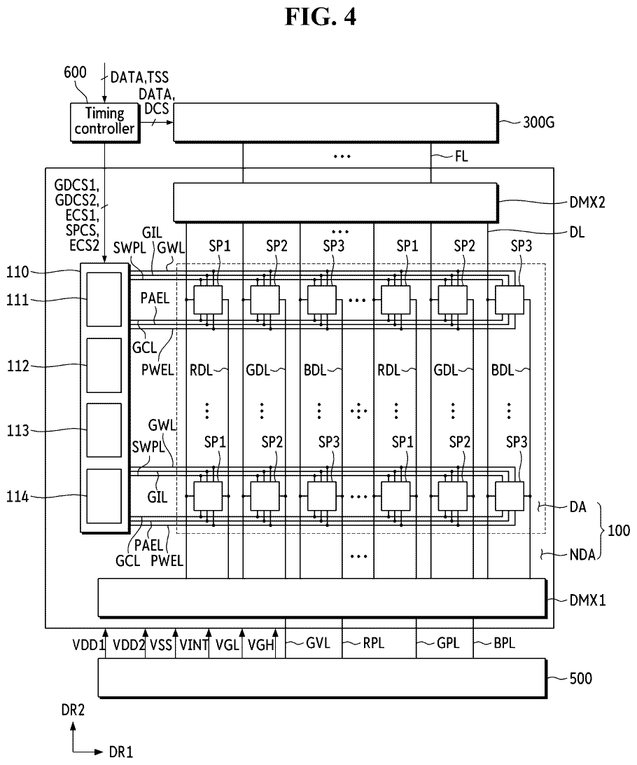

FIG. 4 is a block diagram illustrating the display device according to one or more embodiments.

Referring to FIG. 4, the display device 10 includes a display panel 100, a scan driver 110, a data driver 300G, a timing controller 600, and a power supply unit 500.

A display area DA of the display panel 100 may include sub-pixels SP1, SP2, and SP3 displaying an image, and scan write lines GWL, scan initialization lines GIL, scan control lines GCL, sweep signal lines SWPL, PWM emission lines PWEL, pulse amplitude modulation (PAM) emission lines PAEL, PWM data lines DL, first data lines RDL, second data lines GDL, and third data lines BDL that are connected to the sub-pixels SP1, SP2, and SP3.

The scan write lines GWL, the scan initialization lines GIL, the scan control lines GCL, the sweep signal lines SWPL, the PWM emission lines PWEL, and the PAM emission lines PAEL may extend in the first direction DR1 (X-axis direction), and may be disposed along the second direction DR2 (Y-axis direction) crossing the first direction (X-axis direction). The PWM data lines DL, the first data lines RDL, the second data lines GDL, and the third data lines BDL may extend in the second direction (Y-axis direction), and may be disposed along the first direction (X-axis direction). The first data lines RDL may be electrically connected to each other, the second data lines GDL may be electrically connected to each other, and the third data lines BDL may be electrically connected to each other.

The sub-pixels SP1, SP2, and SP3 may include first sub-pixels SP1 emitting first light, second sub-pixels SP2 emitting second light, and third sub-pixels SP3 emitting third light. The first light refers to light of a red wavelength band, the second light refers to light of a green wavelength band, and the third light refers to light of a blue wavelength band. For example, a main peak wavelength of the first light may be positioned at approximately 600 nm to 750 nm, a main peak wavelength of the second light may be positioned at approximately 480 nm to 560 nm, and a main peak wavelength of the third light may be positioned at approximately 370 nm to 460 nm.

Each of the sub-pixels SP1, SP2, and SP3 may be connected to one of the scan write lines GWL, one of the scan initialization lines GIL, one of the scan control lines GCL, one of the sweep signal lines SWPL, one of the PWM emission lines PWEL, and one of the PAM emission lines PAEL. In addition, each of the first sub-pixels SP1 may be connected to one of the PWM data lines DL and one of the first data lines RDL. In addition, each of the second sub-pixels SP2 may be connected to one of the PWM data lines DL and one of the second data lines GDL. In addition, each of the third sub-pixels SP3 may be connected to one of the PWM data lines DL and one of the third data lines BDL.

A non-display area NDA of the display panel 100 may include the scan driver 110, a first demultiplxer unit DMX1, and a second demultiplxer unit DMX2.

The scan driver 110 for applying signals to the scan write lines GWL, the scan initialization lines GIL, the scan control lines GCL, the sweep signal lines SWPL, the PWM emission lines PWEL, and the PAM emission lines PAEL may be disposed in the non-display area NDA of the display panel 100. It has been illustrated in FIG. 4 that the scan driver 110 is disposed at an edge of one side of the display panel 100, but the present disclosure is not limited thereto. The scan drivers 110 may be disposed at edges of both sides of the display panel 100.

The scan driver 110 may include a first scan signal driver 111, a second scan signal driver 112, a sweep signal driver 113, and an emission signal driver 114.

The first scan signal driver 111 may receive a first scan driving control signal GDCS1 from the timing controller 600. The first scan signal driver 111 may output scan initialization signals to the scan initialization lines GIL and output scan write signals to the scan write lines GWL, according to the first scan driving control signal GDCS1. That is, the first scan signal driver 111 may output two scan signals, that is, the scan initialization signals and the scan write signals together.

The second scan signal driver 112 may receive a second scan driving control signal GDCS2 from the timing controller 600. The second scan signal driver 112 may output scan control signals to the scan control lines GCL according to the second scan driving control signal GDCS2.

The sweep signal driver 113 may receive a first emission control signal ECS1 and a sweep control signal SPCS from the timing controller 600. The sweep signal driver 113 may output PWM emission signals to the PWM emission lines PWEL and output sweep signals to the sweep signal lines SWPL, according to the first emission control signal ECS1. That is, the sweep signal driver 113 may output the PWM emission signals and the sweep signals together.

The emission signal driver 114 may receive a second emission control signal ECS2 from the timing controller 600. The emission signal driver 114 may output PAM emission signals to the PAM emission lines PAEL according to the second emission control signal ECS2.

The first demultiplxer unit DMX1 switches the connection between each PWM data line DL and a global power line GVL. In addition, the first demultiplxer unit DMX1 switches the connection between each first data line RDL and a first data voltage line RPL, switches the connection between each second data line GDL and a second data voltage line GPL, and switches the connection between each third data line BDL and a third data voltage line BPL.

The second demultiplxer unit DMX2 may be disposed between fan-out lines FL and the PWM data lines DL. The second demultiplxer unit DMX2 may divide PWM data voltages applied to the respective fan-out lines FL into Q PWM data lines DL (here, Q is an integer of 2 or more) or Q first to third data lines RDL, GDL, and BDL.

The first demultiplxer unit DMX1 may be disposed adjacent to the second pads, and the second demultiplxer unit DMX2 may be disposed adjacent to the first pads. That is, the first demultiplxer unit DMX1 may be disposed adjacent to one side of the display panel 100, for example, the lower side of the display panel 100. The second demultiplxer unit DMX2 may be disposed adjacent to the other side of the display panel 100, for example, the upper side of the display panel 100.

The timing controller 600 receives digital video data DATA and timing signals TSS. The timing controller 600 may generate the first scan driving control signal GDCS1, the second scan driving control signal GDSC2, the first emission control signal ECS1, the second emission control signal ECS2, and the sweep control signal SPCS for controlling an operation timing of the scan driver 110 according to the timing signals TSS. In addition, the timing controller 600 may generate a PWM control signal DCS for controlling an operation timing of the source driver 300.

The timing controller 600 outputs the first scan driving control signal GDCS1, the second scan driving control signal GDSC2, the first emission control signal ECS1, the second emission control signal ECS2, and the sweep control signal SPCS to the scan driver 110. The timing controller 600 outputs the digital video data DATA and the PWM control signal DCS to the data driver 300G.

The data driver 300G may include a plurality of source drivers 300. The data driver 300G converts the digital video data DATA into analog PWM data voltages and outputs the analog PWM data voltages to the fan-out lines FL.

The power supply unit 500 may generate a first data voltage and output the first data voltage to the first data voltage line RPL, may generate a second data voltage and output the second data voltage to the second data voltage line GPL, and may generate a third data voltage and output the third data voltage to the third data voltage line BPL. The power supply unit 500 may generate the global source voltage GV and output the global source voltage GV to the global power line GVL.

In addition, the power supply unit 500 may generate a plurality of source voltages and output the plurality of source voltages to the display panel 100. For example, the power supply unit 500 may output a first source voltage VDD1, a second source voltage VDD2, a third source voltage VSS, an initialization voltage VINT, a gate-on voltage VGL, and a gate-off voltage VGH to the display panel 100. The first source voltage VDD1 and the second source voltage VDD2 may be high potential driving voltages for driving a light emitting element of each of the sub-pixels SP1, SP2, and SP3. The third source voltage VSS may be a low potential driving voltage for driving the light emitting element of each of the sub-pixels SP1, SP2, and SP3. The initialization voltage VINT and the gate-off voltage VGH may be applied to each of the sub-pixels SP1, SP2, and SP3, and the gate-on voltage VGL and the gate-off voltage VGH may be applied to the scan driver 110.

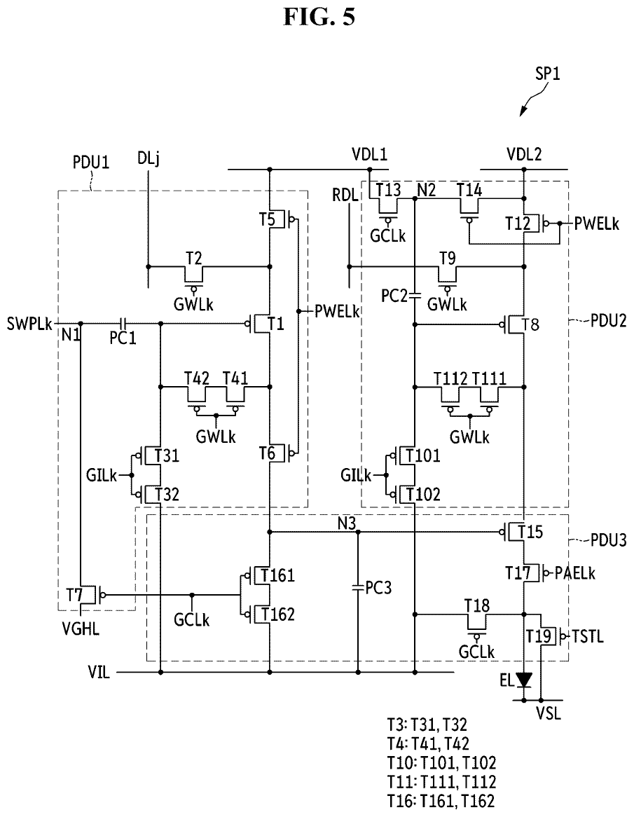

FIG. 5 is a circuit diagram illustrating a first sub-pixel according to one or more embodiments.

Referring to FIG. 5, the first sub-pixel SP1 according to one or more embodiments may be connected to a k-th scan write line GWLk, a k-th scan initialization line GILk, a k-th scan control line GCLk, a k-th sweep signal line SWPLk, a k-th PWM emission line PWELk, and a k-th PAM emission line PAELk. In addition, the first sub-pixel SP1 may be connected to a j-th PWM data line DLj and a first data line RDL. In addition, the first sub-pixel SP1 may be connected to a first power line VDL1 to which the first source voltage VDD1 is applied, a second power line VDL2 to which the second source voltage VDD2 is applied, a third power line VSL to which the third source voltage VSS is applied, an initialization voltage line VIL to which the initialization voltage VINT is applied, and a gate-off voltage line VGHL to which the gate-off voltage VGH is applied. For convenience of explanation, the j-th PWM data line DLj may be referred to as a first data line, and the first data line RDL may be referred to as a second data line.

The first sub-pixel SP1 may include a light emitting element EL, a first pixel driving unit PDU1, a second pixel driving unit PDU2, and a third pixel driving unit PDU3.

The light emitting element EL emits light depending on a driving current generated by the second pixel driving unit PDU2. The light emitting element EL may be disposed between a seventeenth transistor T17 and the third power line VSL. A first electrode of the light emitting element EL may be connected to a second electrode of the seventeenth transistor T17, and a second electrode of the light emitting element EL may be connected to the third power line VSL. The first electrode of the light emitting element EL may be an anode electrode, and the second electrode of the light emitting element EL may be a cathode electrode. The light emitting element EL may be an inorganic light emitting element including a first electrode, a second electrode, and an inorganic semiconductor disposed between the first electrode and the second electrode. For example, the light emitting element EL may be a micro light emitting diode made of an inorganic semiconductor, but is not limited thereto.

The first pixel driving unit PDU1 controls a voltage of a third node N3 of the third pixel driving unit PDU3 by generating a control current according to a j-th PWM data voltage of the j-th PWM data line DLj. Because a pulse width of the driving current flowing to the light emitting element EL may be adjusted by the control current of the first pixel driving unit PDU1, the first pixel driving unit PDU1 may be a pulse width modulation unit (PWM unit) performing pulse width modulation of the driving current flowing to the light emitting element EL.

The first pixel driving unit PDU1 may include first to seventh transistors T1 to T7 and a first capacitor PC1.

The first transistor T1 controls the control current flowing between a first electrode and a second electrode of the first transistor T1 according to a PWM data voltage applied to a gate electrode of the first transistor T1.

The second transistor T2 is turned on by a k-th scan write signal of the k-th scan write line GWLk to supply the PWM data voltage of the j-th PWM data line DLj to the first electrode of the first transistor T1.

The third transistor T3 is turned on by a k-th scan initialization signal of the k-th scan initialization line GILk to connect the initialization voltage line VIL to the gate electrode of the first transistor T1. For this reason, the gate electrode of the first transistor T1 may be discharged to the initialization voltage VINT of the initialization voltage line VIL during a period in which the third transistor T3 is turned on. In this case, a gate-on voltage VGL of the k-th scan initialization signal may be different from the initialization voltage VINT of the initialization voltage line VIL. In particular, because a difference voltage between the gate-on voltage VGL and the initialization voltage VINT is greater than a threshold voltage of the third transistor T3, the third transistor T3 may be stably turned on even after the initialization voltage VINT is applied to the gate electrode of the first transistor T1. Accordingly, when the third transistor T3 is turned on, the initialization voltage VINT may be stably applied to the gate electrode of the first transistor T1 regardless of the threshold voltage of the third transistor T3.

The third transistor T3 may include a first sub-transistor T31 and a second sub-transistor T32 connected to each other in series. For this reason, leakage of a voltage of the gate electrode of the first transistor T1 through the third transistor T3 may be reduced.

The fourth transistor T4 is turned on by the k-th scan write signal of the k-th scan write line GWLk to connect the gate electrode and the second electrode of the first transistor T1 to each other. For this reason, the first transistor T1 may operate as a diode during a period in which the fourth transistor T4 is turned on.

The fourth transistor T4 may include a third sub-transistor T41 and a fourth sub-transistor T42 connected to each other in series. For this reason, leakage of the voltage of the gate electrode of the first transistor T1 through the fourth transistor T4 may be reduced.

The fifth transistor T5 is turned on by a k-th PWM emission signal of the k-th PWM emission line PWELk to connect the first electrode of the first transistor T1 to the first power line VDL1.

The sixth transistor T6 is turned on by the k-th PWM emission signal of the k-th PWM emission line PWELk to connect the second electrode of the first transistor T1 to the third node N3 of the third pixel driving unit PDU3.

The seventh transistor T7 may be turned on by a k-th scan control signal of the k-th scan control line GCLk to supply the gate-off voltage VGH of the gate-off voltage line VGHL to a first node N1 connected to the k-th sweep signal line SWPLk. For this reason, it is possible to prevent a change in voltage of the gate electrode of the first transistor T1 from being reflected in a k-th sweep signal of the k-th sweep signal line SWPLk by the first capacitor PC1 during a period in which the initialization voltage VINT is applied to the gate electrode of the first transistor T1 and a period in which the PWM data voltage of the j-th PWM data line DLj and a threshold voltage Vth1 of the first transistor T1 are programmed.

The first capacitor PC1 may be disposed between the gate electrode of the first transistor T1 and the first node N1. One electrode of the first capacitor PC1 may be connected to the gate electrode of the first transistor T1, and the other electrode of the first capacitor PC1 may be connected to the first node N1.

The first node N1 may be a contact point between the k-th sweep signal line SWPLk, a second electrode of the seventh transistor T7, and the other electrode of the first capacitor PC1.

The second pixel driving unit PDU2 generates the driving current applied to the light emitting element EL according to a first PWM data voltage of the first data line RDL. The second pixel driving unit PDU2 may be a pulse amplitude modulation unit (PAM unit) performing pulse amplitude modulation. The second pixel driving unit PDU2 may be a constant current generating unit generating a constant driving current according to the first PWM data voltage.

In addition, the second pixel driving unit PDU2 of each of the first sub-pixels SP1 may receive the same first PWM data voltage and generate the same driving current, regardless of luminance of the first sub-pixel SP1. Likewise, the second pixel driving unit PDU2 of each of the second sub-pixels SP2 may receive the same second PWM data voltage and generate the same driving current, regardless of luminance of the second sub-pixel SP2. The second pixel driving unit PDU2 of each of the third sub-pixels SP3 may receive the same third PWM data voltage and generate the same driving current, regardless of luminance of the third sub-pixel SP3.

The second pixel driving unit PDU2 may include eighth to fourteenth transistors T8 to T14 and a second capacitor PC2.

The eighth transistor T8 controls the driving current flowing to the light emitting element EL according to a voltage applied to a gate electrode thereof.

The ninth transistor T9 is turned on by the k-th scan write signal of the k-th scan write line GWLk to apply the first PWM data voltage of the first data line RDL to a first electrode of the eighth transistor T8.

The tenth transistor T10 is turned on by the k-th scan initialization signal of the k-th scan initialization line GILk to connect the initialization voltage line VIL to the gate electrode of the eighth transistor T8. For this reason, the gate electrode of the eighth transistor T8 may be discharged to the initialization voltage VINT of the initialization voltage line VIL during a period in which the tenth transistor T10 is turned on. In this case, a gate-on voltage VGL of the k-th scan initialization signal may be different from the initialization voltage VINT of the initialization voltage line VIL. In particular, because a difference voltage between the gate-on voltage VGL and the initialization voltage VINT is greater than a threshold voltage of the tenth transistor T10, the tenth transistor T10 may be stably turned on even after the initialization voltage VINT is applied to the gate electrode of the eighth transistor T8. Accordingly, when the tenth transistor T10 is turned on, the initialization voltage VINT may be stably applied to the gate electrode of the eighth transistor T8 regardless of the threshold voltage of the tenth transistor T10.

The tenth transistor T10 may include a fifth sub-transistor T101 and a sixth sub-transistor T102 connected to each other in series. For this reason, leakage of a voltage of the gate electrode of the eighth transistor T8 through the tenth transistor T10 may be reduced.

The eleventh transistor T11 is turned on by the k-th scan write signal of the k-th scan write line GWLk to connect the gate electrode and a second electrode of the eighth transistor T8 to each other. For this reason, the eighth transistor T8 may operate as a diode during a period in which the eleventh transistor T11 is turned on.

The eleventh transistor T11 may include a seventh sub-transistor T111 and an eighth sub-transistor T112 connected to each other in series. For this reason, leakage of the voltage of the gate electrode of the eighth transistor T8 through the eleventh transistor T11 may be reduced.

The twelfth transistor T12 is turned on by the k-th PWM emission signal of the k-th PWM emission line PWELk to connect the first electrode of the eighth transistor T8 to the second power line VDL2.

The thirteenth transistor T13 is turned on by the k-th scan control signal of the k-th scan control line GCLk to connect the first power line VDL1 to a second node N2.

The fourteenth transistor T14 is turned on by the k-th PWM emission signal of the k-th PWM emission line PWELk to connect the second power line VDL2 to the second node N2. For this reason, when the fourteenth transistor T14 is turned on, the second source voltage VDD2 of the second power line VDL2 may be supplied to the second node N2.

The second capacitor PC2 may be disposed between the gate electrode of the eighth transistor T8 and the second node N2. One electrode of the second capacitor PC2 may be connected to the gate electrode of the eighth transistor T8, and the other electrode of the second capacitor PC2 may be connected to the second node N2.

The second node N2 may be a contact point between a second electrode of the thirteenth transistor T13, a second electrode of the fourteenth transistor T14, and the other electrode of the second capacitor PC2.

The third pixel driving unit PDU3 adjusts a period in which the driving current is applied to the light emitting element EL according to the voltage of the third node N3.

The third pixel driving unit PDU3 may include fifteenth to nineteenth transistors T15 to T19 and a third capacitor PC3.

The fifteenth transistor T15 is turned on or turned off according to the voltage of the third node N3. When the fifteenth transistor T15 is turned on, the driving current of the eighth transistor T8 may be supplied to the light emitting element EL, and when the fifteenth transistor T15 is turned off, the driving current of the eighth transistor T8 may not be supplied to the light emitting element EL. Therefore, a turn-on period of the fifteenth transistor T15 may be substantially the same as an emission period of the light emitting element EL.

The sixteenth transistor T16 is turned on by the k-th scan control signal of the k-th scan control line GCLk to connect the initialization voltage line VIL to the third node N3. For this reason, the third node N3 may be discharged to the initialization voltage of the initialization voltage line VIL during a period in which the sixteenth transistor T16 is turned on.

The sixteenth transistor T16 may include a ninth sub-transistor T161 and a tenth sub-transistor T162 connected to each other in series. For this reason, it is possible to prevent the voltage of the third node N3 from being leaked through the sixteenth transistor T16.

The seventeenth transistor T17 is turned on by a k-th PAM emission signal of the k-th PAM emission line PAELk to connect a second electrode of the fifteenth transistor T15 to the first electrode of the light emitting element EL.

The eighteenth transistor T18 is turned on by the k-th scan control signal of the k-th scan control line GCLk to connect the initialization voltage line VIL to the first electrode of the light emitting element EL. For this reason, the first electrode of the light emitting element EL may be discharged to the third source voltage of the third power line VSL during a period in which the eighteenth transistor T18 is turned on.

The nineteenth transistor T19 is turned on by a test signal of a test signal line TSTL to connect the first electrode of the light emitting element EL to a the third power line VSL. For this reason, by turning on the nineteenth transistor T19 in a test mode, it is possible to sense a voltage or a current of the first electrode of the light emitting element EL using the third power line VSL.

The third capacitor PC3 may be disposed between the third node N3 and the initialization voltage line VIL. One electrode of the third capacitor PC3 may be connected to the third node N3, and the other electrode of the third capacitor PC3 may be connected to the initialization voltage line VIL.

The third node N3 may be a contact point between a second electrode of the sixth transistor T6, a gate electrode of the fifteenth transistor T15, the first electrode of the ninth sub-transistor T161, and one electrode of the third capacitor PC3.

Any one of the first electrode and the second electrode of each of the first to nineteenth transistors T1 to T19 may be a source electrode, and the other one of the first electrode and the second electrode of each of the first to nineteenth transistors T1 to T19 may be a drain electrode. An active layer of each of the first to nineteenth transistors T1 to T19 may be made of polysilicon, amorphous silicon, and/or an oxide semiconductor. When the active layer of each of the first to nineteenth transistors T1 to T19 is made of the polysilicon, the active layer of each of the first to nineteenth transistors T1 to T19 may be formed by a low temperature polysilicon (LTPS) process.

In addition, it has been mainly described in FIG. 5 that each of the first to nineteenth transistors T1 to T19 is formed as a P-type metal oxide semiconductor field effect transistor (MOSFET), but the present disclosure is not limited thereto. For example, each or at least some of the first to nineteenth transistors T1 to T19 may also be formed as N-type MOSFETs.

The second sub-pixel SP2 and the third sub-pixel SP3 according to one or more embodiments may be substantially the same as the first sub-pixel SP1 described with reference to FIG. 5. Therefore, a description of the second sub-pixel SP2 and the third sub-pixel SP3 according to one or more embodiments is omitted.

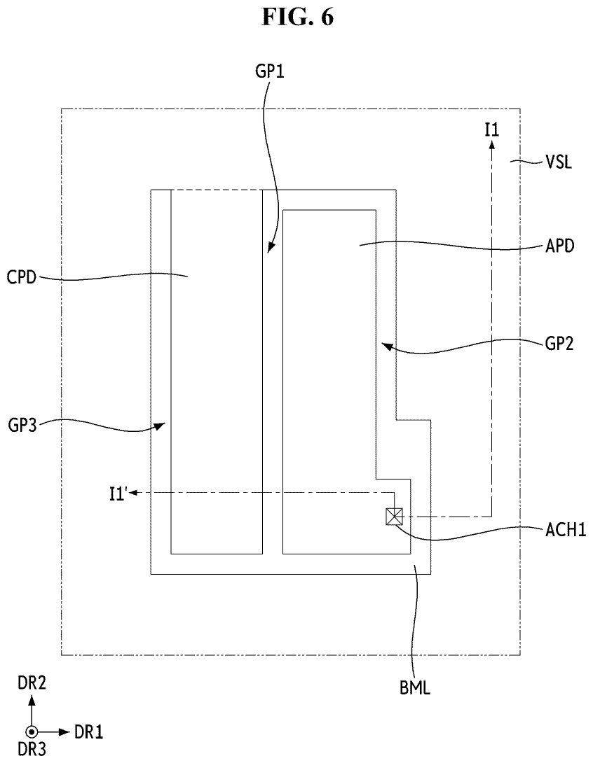

FIG. 6 is a layout diagram illustrating a first pad electrode, a second pad electrode, a third power line, and a lower light blocking pattern of the first sub-pixel according to one or more embodiments.

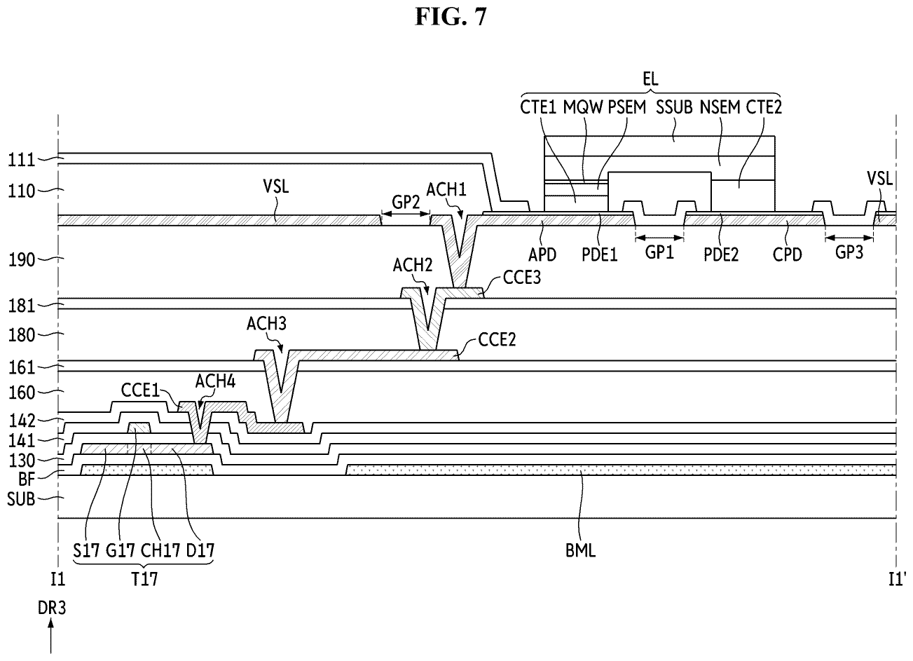

Referring to FIG. 6, a first pad electrode APD, a second pad electrode CPD, and the third power line VSL may be made of the same material and disposed on (e.g., at) the same layer. For example, the first pad electrode APD, the second pad electrode CPD, and the third power line VSL may be included in a fourth source metal layer, and may be disposed on a third planarization film 190 (see FIG. 7).

The first pad electrode APD is an electrode electrically connected to the first electrode of the light emitting element EL, and the second pad electrode CPD is an electrode electrically connected to the second electrode of the light emitting element EL. The first pad electrode APD and the second pad electrode CPD may be electrically disconnected from each other. The first pad electrode APD and the second pad electrode CPD may be disposed to be physically spaced (e.g., spaced apart) from each other.

The first pad electrode APD may be disposed in an island shape. The first pad electrode APD may be connected to a third connection electrode CCE3 (see FIG. 7) through a first connection contact hole ACH1.

The first pad electrode APD may be surrounded by the second pad electrode CPD and the third power line VSL. The second pad electrode CPD may be disposed on a first side of the first pad electrode APD, and the third power line VSL may be disposed on the other sides of the first pad electrode APD. In this case, a first gap GP1 may exist between the first side of the first pad electrode APD and the second pad electrode CPD. In addition, a second gap GP2 may exist between the other sides of the first pad electrode APD and the third power line VSL.

For example, as illustrated in FIG. 6, the second pad electrode CPD may be disposed on the left side of the first pad electrode APD, and the third power line VSL may be disposed on the upper side, the right side, and the lower side of the first pad electrode APD. In this case, the first gap GP1 may exist between the left side of the first pad electrode APD and the second pad electrode CPD, and the second gap GP2 may exist between each of the upper side, the right side, and the lower side of the first pad electrode APD and the third the power line VSL.

A first side of the second pad electrode CPD may be connected to the third power line VSL, the third power line VSL may be disposed on a second side and a third side of the second pad electrode CPD, and the first pad electrode APD may be disposed on a fourth side of the second pad electrode CPD. The first side and the third side of the second pad electrode CPD may face each other, and the second side and the fourth side of the second pad electrode CPD may face each other. The second pad electrode CPD and the third power line VSL may be formed integrally with each other.

A third gap GP3 may exist between each of the second side and the third side of the second pad electrode CPD and the third power line VSL, and the first gap GP1 may exist between the fourth side of the second pad electrode CPD and the first pad electrode APD.

For example, the upper side of the second pad electrode CPD may be connected to the third power line VSL, the third power line VSL may be disposed on the left side and the lower side of the second pad electrode CPD, and the first pad electrode APD may be disposed on the right side of the second pad electrode CPD. In this case, the third gap GP3 may exist between each of the left side and the lower side of the second pad electrode CPD and the third power line VSL, and the first gap GP1 may exist between the right side of the second pad electrode CPD and the first pad electrode APD.

A lower light blocking pattern BML may overlap the first gap GP1, the second gap GP2, and the third gap GP3. Therefore, light traveling in a downward direction of the display panel 100 through the first gap GP1, the second gap GP2, and the third gap GP3 from among light emitted from the light emitting element EL disposed on the first pad electrode APD and the second pad electrode CPD may be blocked by the lower light blocking pattern BML. Therefore, it is possible to improve a phenomenon in which the light emitted from the light emitting element EL is reflected from the lines and the device identifier DID disposed on a back surface of the display panel 100 and is viewed as back surface reflection.

A first pad electrode APD, a second pad electrode CPD, a third power line VSL, and a lower light blocking pattern BML of each of the second sub-pixel SP2 and the third sub-pixel SP3 according to one or more embodiments may be substantially the same as the first pad electrode APD, the second pad electrode CPD, the third power line VSL, and the lower light blocking pattern BML of the first sub-pixel SP1 described with reference to FIG. 6. Therefore, a description of the first pad electrode APD, the second pad electrode CPD, the third power line VSL, and the lower light blocking pattern BML of each of the second sub-pixel SP2 and the third sub-pixel SP3 according to one or more embodiments is omitted.

FIG. 7 is a cross-sectional view illustrating an example of a display panel taken along the line I1-I1′ of FIG. 6.

Referring to FIG. 7, the display panel 100 may include a substrate SUB, a thin film transistor layer, and a light emitting element layer.

The substrate SUB may be made of an insulating material such as glass and/or a polymer resin. For example, when the substrate SUB is made of the polymer resin, the substrate SUB may include polyimide. The substrate SUB may be a flexible substrate that may be bent, folded, and/or rolled.

The thin film transistor layer may be disposed on the substrate SUB. The thin film transistor layer includes the first to nineteenth transistors T1 to T19 illustrated in FIG. 5, the lower light blocking pattern BML, a buffer film BF, and a plurality of insulating films 130, 141, 142, 160, 161, 180, 181, and 190.

The lower light blocking pattern BML may be disposed on the substrate SUB. The lower light blocking pattern BML may overlap the first gap GP1, the second gap GP2, and the third gap GP3 in a third direction DR3 (e.g., a thickness direction of the substrate SUB). Therefore, light traveling in a downward direction of the substrate SUB through the first gap GP1, the second gap GP2, and the third gap GP3 from among light emitted from the light emitting element EL disposed on the first pad electrode APD and the second pad electrode CPD may be blocked by the lower light blocking pattern BML. Therefore, it is possible to improve a phenomenon in which the light emitted from the light emitting element EL is reflected from the lines and the device identifier DID disposed on the back surface of the display panel 100 and is viewed as back surface reflection.

The lower light blocking pattern BML may be formed as a single layer or multiple layers made of molybdenum (Mo), aluminum (Al), chromium (Cr), gold (Au), titanium (Ti), nickel (Ni), neodymium (Nd), and/or copper (Cu), and/or alloys thereof. The lower light blocking pattern BML may be formed to have a thickness of approximately 3,000 Å or more in order to serve as a light blocking structure.

The buffer film BF may be disposed on the lower light blocking pattern BML and the substrate SUB. The buffer film BF may include a plurality of inorganic films that are alternately stacked. For example, the buffer film BF may be formed as multiple films in which one or more inorganic films of a silicon nitride layer, a silicon oxynitride layer, a silicon oxide layer, a titanium oxide layer, and/or an aluminum oxide layer are alternately stacked.

The first to nineteenth transistors T1 to T19 may be disposed on the buffer film BF. The first to nineteenth transistors T1 to T19 may be formed as thin film transistors. For convenience of explanation, only the seventeenth transistor T17 of the first to nineteenth transistors T1 to T19 has been illustrated in FIG. 7.

An active layer of the seventeenth transistor T17 may be disposed on the buffer film BF. The active layer of the seventeenth transistor T17 includes a channel CH17, a source electrode S17, and a drain electrode D17.

A gate insulating film 130 may be disposed on the active layer of the seventeenth transistor T17 and the buffer film BF. The gate insulating film 130 may be formed as an inorganic insulating film such as a silicon nitride (SiNₓ) film, a silicon oxide (SiOₓ) film, a silicon oxynitride (SiON) film, a titanium oxide (TiOₓ) film, and/or an aluminum oxide (AlOₓ) film.

A first gate metal layer may be disposed on the gate insulating film 130. The first gate metal layer includes a gate electrode G17 of the seventeenth transistor T17. The gate electrode G17 of the seventeenth transistor T17 may overlap the channel CH17 in the third direction DR3, which is a thickness direction of the substrate SUB. The first gate metal layer may be formed as a single layer or multiple layers made of molybdenum (Mo), aluminum (Al), chromium (Cr), gold (Au), titanium (Ti), nickel (Ni), neodymium (Nd), and/or copper (Cu), and/or alloys thereof.

A first interlayer insulating film 141 may be disposed on the first gate metal layer and the gate insulating film 130. The first interlayer insulating film 141 may be formed as an inorganic insulating film such as a silicon nitride (SiNₓ) film, a silicon oxide (SiOₓ) film, a silicon oxynitride (SiON) film, a titanium oxide (TiOₓ) film, and/or an aluminum oxide (AlOₓ) film.

A second gate metal layer may be disposed on the first interlayer insulating film 141. The second gate metal layer may be formed as a single layer or multiple layers made of molybdenum (Mo), aluminum (Al), chromium (Cr), gold (Au), titanium (Ti), nickel (Ni), neodymium (Nd), and/or copper (Cu), and/or alloys thereof.

A second interlayer insulating film 142 may be disposed on the second gate metal layer and the first interlayer insulating film 141. The second interlayer insulating film 142 may be formed as an inorganic insulating film such as a silicon nitride (SiNₓ) film, a silicon oxide (SiOₓ) film, a silicon oxynitride (SiON) film, a titanium oxide (TiOₓ) film, and/or an aluminum oxide (AlOₓ) film.

A first source metal layer may be disposed on the second interlayer insulating film 142. The first source metal layer includes a first connection electrode CCE1. The first connection electrode CCE1 may be connected to the drain electrode D17 of the seventeenth transistor T17 through a fourth connection contact hole ACH4 penetrating through the gate insulating film 130, the first interlayer insulating film 141, and the second interlayer insulating film 142. The first source metal layer may be formed as a single layer or multiple layers made of molybdenum (Mo), aluminum (Al), chromium (Cr), gold (Au), titanium (Ti), nickel (Ni), neodymium (Nd), and/or copper (Cu), and/or alloys thereof.

A first planarization film 160 may be disposed on the first source metal layer and the second interlayer insulating film 142. The first planarization film 160 may be formed as an organic insulating film made of an acrylic resin, an epoxy resin, a phenolic resin, a polyamide resin, a polyimide resin, and/or the like.

A first inorganic insulating film 161 may be disposed on the first planarization layer 160. The first inorganic insulating film 161 may be formed as a silicon nitride (SiNₓ) film, a silicon oxide (SiOₓ) film, a silicon oxynitride (SiON) film, a titanium oxide (TiOₓ) film, and/or an aluminum oxide (AlOₓ) film.

A second source metal layer may be disposed on the first inorganic insulating film 161. The second source metal layer includes a second connection electrode CCE2. The second connection electrode CCE2 may be connected to the first connection electrode CCE1 through a third connection contact hole ACH3 penetrating through the first planarization film 160 and the first inorganic insulating film 161. The second source metal layer may be formed as a single layer or multiple layers made of molybdenum (Mo), aluminum (Al), chromium (Cr), gold (Au), titanium (Ti), nickel (Ni), neodymium (Nd), and/or copper (Cu), and/or alloys thereof.

A second planarization film 180 may be disposed on the second source metal layer and the first inorganic insulating film 161. The second planarization film 180 may be formed as an organic insulating film made of an acrylic resin, an epoxy resin, a phenolic resin, a polyamide resin, a polyimide resin, and/or the like.

A second inorganic insulating film 181 may be disposed on the second planarization layer 180. The second inorganic insulating film 181 may be formed as a silicon nitride (SiNₓ) film, a silicon oxide (SiOₓ) film, a silicon oxynitride (SiON) film, a titanium oxide (TiOₓ) film, and/or an aluminum oxide (AlOₓ) film.

A third source metal layer may be disposed on the second inorganic insulating film 181. The third source metal layer includes the third connection electrode CCE3. The third connection electrode CCE3 may be connected to the second connection electrode CCE2 through a second connection contact hole ACH2 penetrating through the second planarization film 180 and the second inorganic insulating film 181. The third source metal layer may be formed as a single layer or multiple layers made of molybdenum (Mo), aluminum (Al), chromium (Cr), gold (Au), titanium (Ti), nickel (Ni), neodymium (Nd), and/or copper (Cu), and/or alloys thereof.

A third planarization film 190 may be disposed on the third source metal layer and the second inorganic insulating film 181. The third planarization film 190 may be formed as an organic insulating film made of an acrylic resin, an epoxy resin, a phenolic resin, a polyamide resin, a polyimide resin, and/or the like.

A fourth source metal layer may be disposed on the third planarization film 190. The fourth source metal layer includes the first pad electrode APD, the second pad electrode CPD, and the third power line VSL. The first pad electrode APD may be connected to the third connection electrode CCE3 through the first connection contact hole ACH1 penetrating through the third planarization film 190.

The fourth source metal layer may be formed as a single layer or multiple layers made of molybdenum (Mo), aluminum (Al), chromium (Cr), gold (Au), titanium (Ti), nickel (Ni), neodymium (Nd), and/or copper (Cu), and/or alloys thereof.

A first pad connection electrode PDE1 may be disposed on the first pad electrode APD, and a second pad connection electrode PDE2 may be disposed on the second pad electrode CPD. A thickness of the first pad connection electrode PDE1 may be smaller than a thickness of the first pad electrode APD, and a thickness of the second pad connection electrode PDE2 may be smaller than a thickness of the second pad electrode CPD.

The first pad connection electrode PDE1 may be electrically connected to a first electrode CTE1 of the light emitting element EL, and the second pad connection electrode PDE2 may be electrically connected to a second electrode CTE2 of the light emitting element EL. Each of the first pad connection electrode PDE1 and the second pad connection electrode PDE2 may be made of a transparent conductive material (TCO) such as indium tin oxide (ITO) and/or indium zinc oxide (IZO).

A fourth planarization film 110 may be disposed on a partial area of the first pad electrode APD and the third power line VSL. The fourth planarization film 110 may be formed as an organic insulating film made of an acrylic resin, an epoxy resin, a phenolic resin, a polyamide resin, a polyimide resin, and/or the like.

A fourth inorganic insulating film 111 may be disposed on the fourth planarization layer 110. The fourth inorganic insulating film 111 may be disposed to cover edges of the first pad electrode APD and edges of the second pad electrode CPD. The fourth inorganic insulating film 111 may be formed as a silicon nitride (SiNₓ) film, a silicon oxide (SiOₓ) film, a silicon oxynitride (SiON) film, a titanium oxide (TiOₓ) film, and/or an aluminum oxide (AlOₓ) film.

The light emitting element layer may be disposed on the first pad connection electrode PDE1 and the second pad connection electrode PDE2. The light emitting element layer may include light emitting elements EL.

It has been illustrated that the light emitting element EL is a flip chip-type micro LED whose first electrode CTE1 faces the first pad electrode APD and second electrode CTE2 faces the second pad electrode CPD. The light emitting element EL may be made of an inorganic material such as gallium nitride (GaN). Each of lengths of the light emitting element EL in the first direction DR1, the second direction DR2, and the third direction DR3 may be several to several hundred micrometers. For example, each of lengths of the light emitting element EL in the first direction DR1, the second direction DR2, and the third direction DR3 may be approximately 100 μm or less.

The light emitting elements EL may be grown and formed on a semiconductor substrate such as a silicon wafer. Each of the light emitting elements EL may be directly transferred from the silicon wafer onto the first pad connection electrode PDE1 and the second pad connection electrode PDE2 of the substrate SUB. Alternatively, each of the light emitting elements EL may be transferred onto the first pad connection electrode PDE1 and the second pad connection electrode PDE2 of the substrate 100 through an electrostatic method using an electrostatic head or a stamp method using an elastic polymer material such as polydimethylsiloxane (PDMS) and/or silicon as a material of a transfer substrate.

The light emitting element EL may be a light emitting structure including a base substrate SSUB, an n-type semiconductor NSEM, an active layer MQW, a p-type semiconductor PSEM, the first electrode CTE1, and the second electrode CTE2.

The base substrate SSUB may be a sapphire substrate, but the present disclosure is not limited thereto.

The n-type semiconductor NSEM may be disposed on one surface of the base substrate SSUB. For example, the n-type semiconductor NSEM may be disposed on a lower surface of the base substrate SSUB. The n-type semiconductor NSEM may be made of GaN doped with an n-type dopant such as Si, Ge, and/or Sn.

The active layer MQW may be disposed on a portion of one surface of the n-type semiconductor NSEM. The active layer MQW may include a material having a single or multiple quantum well structure. When the active layer MQW includes the material having the multiple quantum well structure, the active layer MQW may have a structure in which a plurality of well layers and barrier layers are alternately stacked. In this case, the well layer may be made of InGaN, and the barrier layer may be made of GaN or AlGaN, but the present disclosure is not limited thereto. Alternatively, the active layer MQW may have a structure in which semiconductor materials having high band gap energy and semiconductor materials having small band gap energy are alternately stacked, and may include other Group III to Group V semiconductor materials depending on a wavelength band of emitted light.

The p-type semiconductor PSEM may be disposed on one surface of the active layer MQW. The p-type semiconductor PSEM may be made of GaN doped with a p-type dopant such as Mg, Zn, Ca, Se, and/or Ba.

The first electrode CTE1 may be disposed on the p-type semiconductor PSEM, and the second electrode CTE2 may be disposed on another portion of one surface of the n-type semiconductor NSEM. Another portion of one surface of the n-type semiconductor NSEM on which the second electrode CTE2 is disposed may be disposed to be spaced (e.g., spaced apart) from a portion of one surface of the n-type semiconductor NSEM on which the active layer MQW is disposed.

The first electrode CTE1 may be attached to the first pad connection electrode PDE1 through a conductive adhesive member such as an anisotropic conductive film (ACF) or an anisotropic conductive paste (ACP). Alternatively, the first electrode CTE1 may be attached to the first pad connection electrode PDE1 through a soldering process.

The second electrode CTE2 may be bonded to the second pad connection electrode PDE2 through a conductive adhesive member such as an ACF or an ACP. Alternatively, the second electrode CTE2 may be attached to the second pad connection electrode PDE2 through a soldering process.

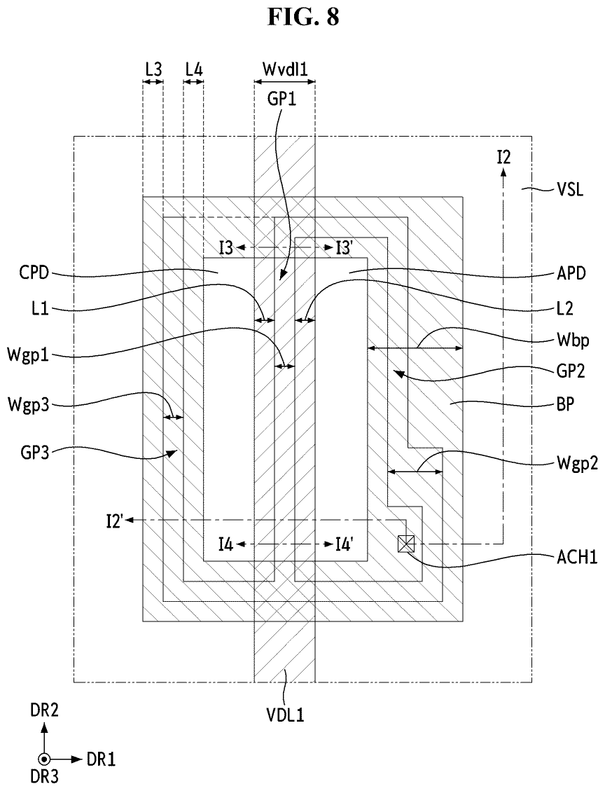

FIG. 8 is a layout diagram illustrating a first pad electrode, a second pad electrode, a first power line, a third power line, and a pad light blocking pattern of the first sub-pixel according to one or more embodiments.

The embodiment of FIG. 8 is different from the embodiment of FIG. 6 in that a first power line VDL1 and a pad light blocking pattern BP are added. In the embodiment of FIG. 8, a description of contents overlapping those of the embodiment of FIG. 6 is omitted.

Referring to FIG. 8, when the lower light blocking pattern BML is made of a metal material having high light transmissivity or is formed to have a thickness smaller than 3,000 Å, light emitted from the light emitting element EL may be transmitted through the lower light blocking pattern BML. In this case, the light emitted from the light emitting element EL may be reflected from the lines and the device identifier DID disposed on the back surface of the display panel 100 and may be viewed as back surface reflection. Therefore, it is necessary to block the light traveling in the downward direction of the display panel 100 through the first gap GP1, the second gap GP2, and the third gap GP3 by other lines or light blocking patterns as well as the lower light blocking pattern BML.

The first power line VDL1 may overlap the first gap GP1 between the first pad electrode APD and the second pad electrode CPD. A thickness of the first power line VDL1 may be greater than a thickness of the lower light blocking pattern BML. For example, the thickness of the lower light blocking pattern BML may be approximately 500 Å to 1,500 Å, and the thickness of the first power line VDL1 may be approximately 2,500 Å or more. Therefore, even though the lower light blocking pattern BML is formed to have a thickness smaller than 3,000 Å, the light traveling in the downward direction of the display panel 100 through the first gap GP1 from among the light emitted from the light emitting element EL disposed on the first pad electrode APD and the second pad electrode CPD may be blocked by the first power line VDL1 and the lower light blocking pattern BML.

The first power line VDL1 may extend in the second direction DR2. A maximum width Wvdl1 of the first power line VDL1 may be greater than a maximum width Wgp1 of the first gap GP1. For example, each of a distance L1 between one side of the first power line VDL1 and one side of the first gap GP1 adjacent to one side of the first power line VDL1 and a distance L2 between the other side of the first power line VDL1 and the other side of the first gap GP1 adjacent to the other side of the first power line VDL1 may be at least 5 μm or more.

In addition, the pad light blocking pattern BP may overlap the second gap GP2 between the first pad electrode APD and the third power line VSL and the third gap GP3 between the second pad electrode CPD and the third power line VSL. A thickness of the pad light blocking pattern BP may be greater than the thickness of the lower light blocking pattern BML. For example, the thickness of the lower light blocking pattern BML may be approximately 500 Å to 1,500 Å, and the thickness of the pad light blocking pattern BP may be approximately 2,500 Å or more. Therefore, even though the lower light blocking pattern BML is formed to have a thickness smaller than 3,000 Å, light traveling in the downward direction of the display panel 100 through the second gap GP2 and the third gap GP3 from among the light emitted from the light emitting element EL disposed on the first pad electrode APD and the second pad electrode CPD may be blocked by the pad light blocking pattern BP and the lower light blocking pattern BML.

The pad light blocking pattern BP may have a rectangular frame shape or a rectangular window frame shape in a plan view. The pad light blocking pattern BP may overlap a portion where the second pad electrode CPD and the third power line VSL are connected to each other.

The pad light blocking pattern BP may be electrically floated. That is, the pad light blocking pattern BP may not be connected to another electrode and line.

A maximum width Wbp of the pad light blocking pattern BP may be greater than each of a maximum width Wgp2 of the second gap GP2 and a maximum width Wgp3 of the third gap GP3. For example, each of a distance between an outer side of the pad light blocking pattern BP and one side of the second gap GP2 adjacent to the outer side of the pad light blocking pattern BP and a distance between an inner side of the pad light blocking pattern BP and the other side of the second gap GP2 adjacent to the inner side of the pad light blocking pattern BP may be at least 5 μm or more. In addition, each of a distance between an outer side of the pad light blocking pattern BP and one side of the third gap GP3 adjacent to the outer side of the pad light blocking pattern BP and a distance between an inner side of the pad light blocking pattern BP and the other side of the third gap GP3 adjacent to the inner side of the pad light blocking pattern BP may be at least 5 μm or more.

In summary, as illustrated in FIG. 8, the phenomenon in which the light emitted from the light emitting element EL is reflected from the lines and the device identifier DID disposed on the back surface of the display panel 100 and is viewed as the back surface reflection may be improved by the first power line VDL1 and the pad light blocking pattern BP.

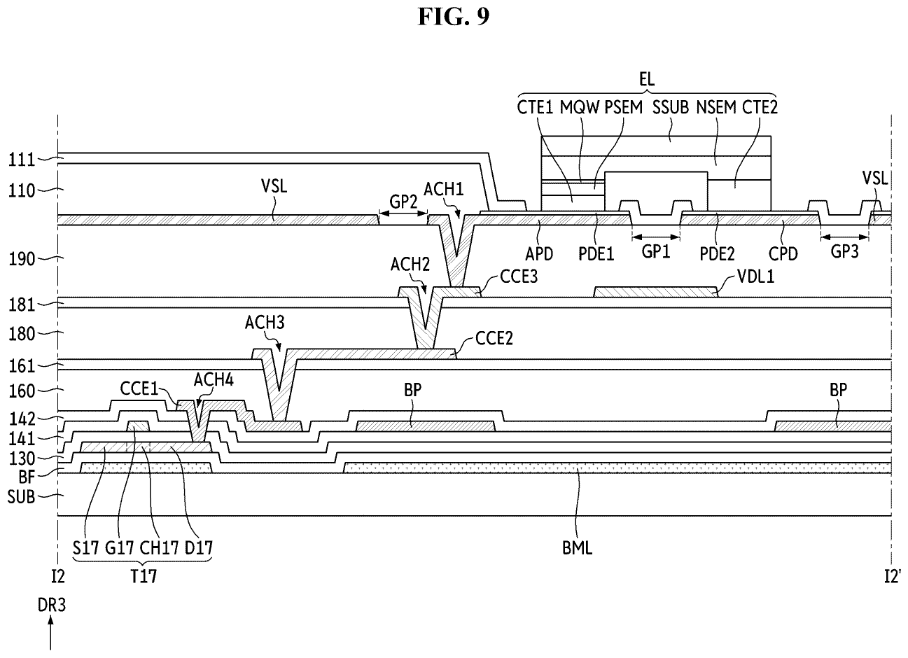

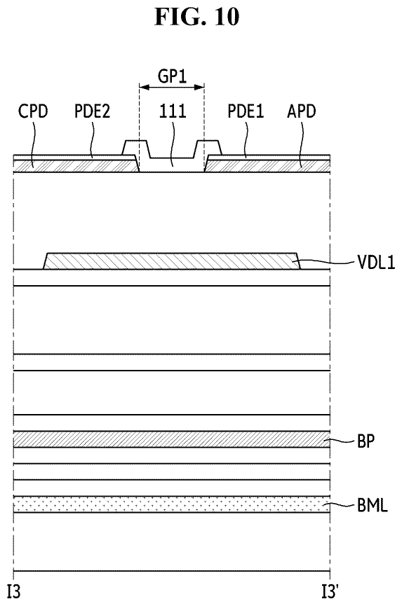

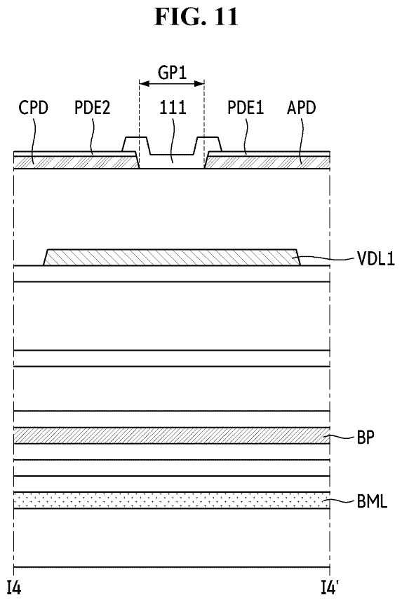

FIG. 9 is a cross-sectional view illustrating an example of the display panel taken along the line I2-I2′ of FIG. 8. FIG. 10 is a cross-sectional view illustrating an example of the display panel taken along the line I3-I3′ of FIG. 8. FIG. 11 is a cross-sectional view illustrating an example of the display panel taken along the line I4-I4′ of FIG. 8.

Referring to FIGS. 9-11, the pad light blocking pattern BP may be included in the second gate metal layer. The pad light blocking pattern BP may be disposed on the first interlayer insulating film 141. The pad light blocking pattern BP may be covered by the second interlayer insulating film 142.

The pad light blocking pattern BP may overlap the second gap GP2 and the third gap GP3 in the third direction DR3. Therefore, the light traveling in the downward direction of the display panel 100 through the second gap GP2, and the third gap GP3 from among the light emitted from the light emitting element EL disposed on the first pad electrode APD and the second pad electrode CPD may be blocked by the pad light blocking pattern BP.

The pad light blocking pattern BP may be disposed in an area overlapping the second gap GP2 and the third gap GP3, whereas the lower light blocking pattern BML may be disposed in a wider area than the pad light blocking pattern BP. Therefore, an area of the lower light blocking pattern BML may be greater than an area of the pad light blocking pattern BP.

The first power line VDL1 may be disposed at the third source metal layer. The first power line VDL1 may be disposed on the second inorganic insulating film 181. The first power line VDL1 may be covered by the third planarization film 190.

The first power line VDL1 may overlap the first gap G1 in the third direction DR3. Therefore, the light traveling in the downward direction of the display panel 100 through the first gap GP1 from among the light emitted from the light emitting element EL disposed on the first pad electrode APD and the second pad electrode CPD may be blocked by the first power line VDL1.

It has been illustrated in FIGS. 9-11 that the pad light blocking pattern BP is included in the second gate metal layer because there is no second gate metal layer overlapping the first pad electrode APD and the second pad electrode CPD in the third direction DR3, but the present disclosure is not limited thereto. For example, when there is no first gate metal layer overlapping the first pad electrode APD and the second pad electrode CPD in the third direction DR3, the pad light blocking pattern BP may be included in the first gate metal layer including the gate electrode G17 of the seventeenth transistor T17. Alternatively, when there is no first source metal layer overlapping the first pad electrode APD and the second pad electrode CPD in the third direction DR3, the pad light blocking pattern BP may be disposed at the first source metal layer including the first connection electrode CCE1.

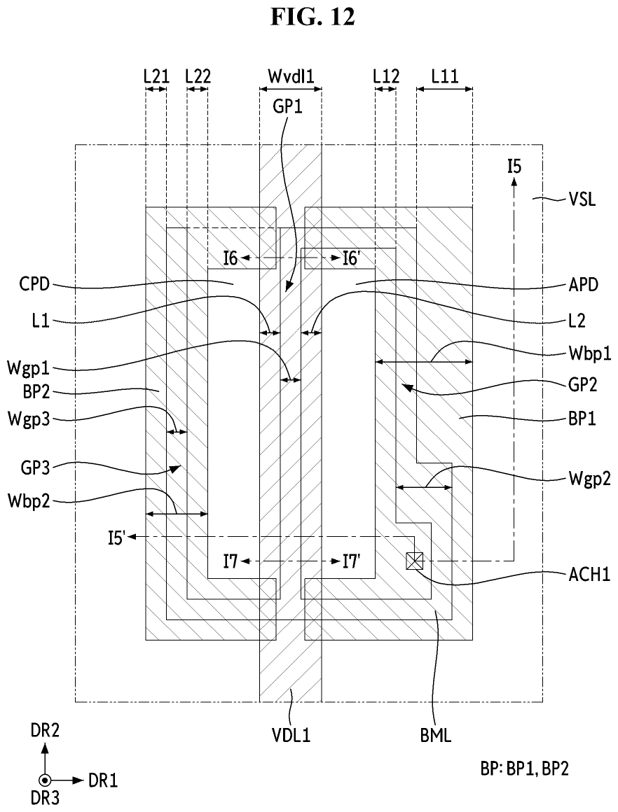

FIG. 12 is a layout diagram illustrating a first pad electrode, a second pad electrode, a first power line, a third power line, a first pad light blocking pattern, and a second pad light blocking pattern of the first sub-pixel according to one or more embodiments.

The embodiment of FIG. 12 is different from the embodiment of FIG. 8 in that the pad light blocking pattern BP includes a first pad light blocking pattern BP1 and a second pad light blocking pattern BP2 disposed to be spaced (e.g., spaced apart) from each other. In FIG. 12, a description of contents overlapping those of the embodiment of FIG. 8 is omitted.

Referring to FIG. 12, the pad light blocking pattern BP includes the first pad light blocking pattern BP1 overlapping the first pad electrode APD in the third direction DR3 and the second pad light blocking pattern BP2 overlapping the second pad electrode CPD in the third direction DR3.

The first pad light blocking pattern BP1 may overlap the second gap GP2 between the first pad electrode APD and the third power line VSL. The first pad light blocking pattern BP1 may be disposed along the second gap GP2. The second gap GP2 may be disposed on the upper side, the right side, and the lower side of the first pad electrode APD, and the first pad light blocking pattern BP1 may overlap the upper side, the right side, and the lower side of the first pad electrode APD in the third direction DR3.

A thickness of the first pad light blocking pattern BP1 may be greater than a thickness of the lower light blocking pattern BML. For example, the thickness of the lower light blocking pattern BML may be approximately 500 Å to 1,500 Å, and the thickness of the first pad light blocking pattern BP1 may be approximately 2,500 Å or more. Therefore, even though the lower light blocking pattern BML is formed to have a thickness smaller than 2,500 Å, light traveling in the downward direction of the display panel 100 through the second gap GP2 from among the light emitted from the light emitting element EL disposed on the first pad electrode APD and the second pad electrode CPD may be blocked by the first pad light blocking pattern BP1 and the lower light blocking pattern BML.

A maximum width Wbp1 of the first pad light blocking pattern BP1 may be greater than a maximum width Wgp2 of the second gap GP2. For example, each of a distance L11 between an outer side of the first pad light blocking pattern BP1 and one side of the second gap GP2 adjacent to the outer side of the first pad light blocking pattern BP1 and a distance L12 between an inner side of the first pad light blocking pattern BP1 and the other side of the second gap GP2 adjacent to the inner side of the first pad light blocking pattern BP1 may be at least 5 μm or more.

The second pad light blocking pattern BP2 may overlap the third gap GP3 between the second pad electrode CPD and the third power line VSL. The second pad light blocking pattern BP2 may be disposed along the third gap GP3. The third gap GP3 may be disposed on the upper side, the right side, and the lower side of the second pad electrode CPD, and the second pad light blocking pattern BP2 may overlap the upper side, the right side, and the lower side of the second pad electrode CPD in the third direction DR3.

A thickness of the second pad light blocking pattern BP2 may be greater than the thickness of the lower light blocking pattern BML. For example, the thickness of the lower light blocking pattern BML may be approximately 500 Å to 1,500 Å, and the thickness of the second pad light blocking pattern BP2 may be approximately 2,500 Å or more. Therefore, even though the lower light blocking pattern BML is formed to have a thickness smaller than 2,500 Å, light traveling in the downward direction of the display panel 100 through the third gap GP3 from among the light emitted from the light emitting element EL disposed on the first pad electrode APD and the second pad electrode CPD may be blocked by the second pad light blocking pattern BP2 and the lower light blocking pattern BML.

The second pad light blocking pattern BP2 may overlap a portion where the second pad electrode CPD and the third power line VSL are connected to each other.

A maximum width Wbp2 of the second pad light blocking pattern BP2 may be greater than a maximum width Wgp3 of the third gap GP3. For example, each of a distance L21 between an outer side of the second pad light blocking pattern BP2 and one side of the third gap GP3 adjacent to the outer side of the second pad light blocking pattern BP2 and a distance L22 between an inner side of the second pad light blocking pattern BP2 and the other side of the third gap GP3 adjacent to the inner side of the second pad light blocking pattern BP2 may be at least 5 μm or more.

In addition, the first pad light blocking pattern BP1 and the second pad light blocking pattern BP2 are disposed to be spaced (e.g., spaced apart) from each other, but the first gap GP1 between the first pad light blocking pattern BP1 and the second pad light blocking pattern BP2 overlaps the first power line VDL1 in the third direction DR3. Therefore, the light traveling in the downward direction of the display panel 100 through the first gap GP1 between the first pad light blocking pattern BP1 and the second pad light blocking pattern BP2 from among the light emitted from the light emitting element EL disposed on the first pad electrode APD and the second pad electrode CPD may be blocked by the first power line VDL1.

In summary, as illustrated in FIG. 12, the phenomenon in which the light emitted from the light emitting element EL is reflected from the lines and the device identifier DID disposed on the back surface of the display panel 100 and is viewed as the back surface reflection may be improved by the first power line VDL1 and the pad light blocking pattern BP.

The first pad light blocking pattern BP1 and the second pad light blocking pattern BP2 may be electrically floated. That is, the first pad light blocking pattern BP1 and the second pad light blocking pattern BP2 may not be connected to other electrodes and lines.

Because the first pad light blocking pattern BP1 and the second pad light blocking pattern BP2 are disposed to be spaced (e.g., spaced apart) from each other, each of an area of the first pad light blocking pattern BP1 and an area of the second pad light blocking pattern BP2 may be smaller than the area of the pad light blocking pattern BP of FIG. 8.

Because the area of the first pad light blocking pattern BP1 is smaller than the area of the pad light blocking pattern BP of FIG. 8, a magnitude of parasitic capacitance formed by the overlap between the first pad light blocking pattern BP1 and another electrode or line in the third direction DR3 may be smaller than a magnitude of parasitic capacitance formed by the overlap between the pad light blocking pattern BP of FIG. 8 and another electrode or line. Therefore, it is possible to reduce an influence of the parasitic capacitance of the first pad light blocking pattern BP1 on another electrode or line overlapping the first pad light blocking pattern BP1 in the third direction DR3.

In addition, because the area of the second pad light blocking pattern BP2 is smaller than the area of the pad light blocking pattern BP of FIG. 8, a magnitude of parasitic capacitance formed by the overlap between the second pad light blocking pattern BP2 and another electrode or line in the third direction DR3 may be smaller than the magnitude of the parasitic capacitance formed by the overlap between the pad light blocking pattern BP of FIG. 8 and another electrode or line. Therefore, it is possible to reduce an influence of the parasitic capacitance of the second pad light blocking pattern BP2 on another electrode or line overlapping the second pad light blocking pattern BP2 in the third direction DR3.

A cross section of the display panel taken along the line I5-I5′ of FIG. 12 is substantially the same as a cross section of the display panel taken along the line I2-I2′ of FIG. 9. Therefore, a description of the cross section of the display panel taken along the line I5-I5′ of FIG. 12 is omitted.

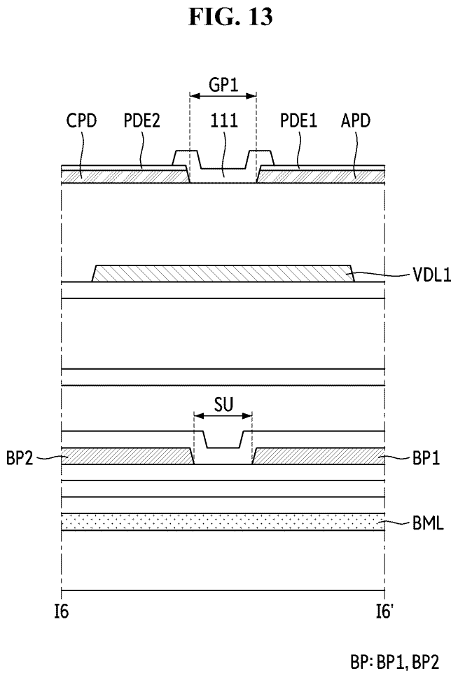

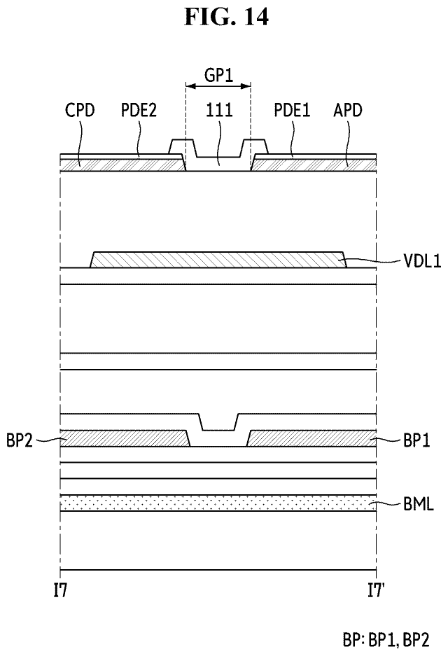

FIG. 13 is a cross-sectional view illustrating an example of the display panel taken along the line I6-I6′ of FIG. 12. FIG. 14 is a cross-sectional view illustrating an example of the display panel taken along the line I7-I7′ of FIG. 12.

Referring to FIGS. 13 and 14, the first pad light blocking pattern BP1 and the second pad light blocking pattern BP2 may be included in the second gate metal layer. The first pad light blocking pattern BP1 and the second pad light blocking pattern BP2 may be disposed on the first interlayer insulating film 141. The first pad light blocking pattern BP1 and the second pad light blocking pattern BP2 may be covered by the second interlayer insulating film 142.

The first pad light blocking pattern BP1 and the second pad light blocking pattern BP2 may overlap the second gap GP2 and the third gap GP3 in the third direction DR3, respectively. Therefore, the light traveling in the downward direction of the display panel 100 through the second gap GP2, and the third gap GP3 from among the light emitted from the light emitting element EL disposed on the first pad electrode APD and the second pad electrode CPD may be blocked by the first pad light blocking pattern BP1 and the second pad light blocking pattern BP2.

The first pad light blocking pattern BP1 may be disposed in an area overlapping the second gap GP2 and the second pad light blocking pattern BP2 may be disposed in an area overlapping the third gap GP3, whereas the lower light blocking pattern BML may be disposed in a wider area than the first pad light blocking pattern BP1 and the second pad light blocking pattern BP2. Therefore, an area of the lower light blocking pattern BML may be greater than the area of the first pad light blocking pattern BP1 and the area of the second pad light blocking pattern BP2.

The first power line VDL1 may be disposed at the third source metal layer. The first power line VDL1 may be disposed on the second inorganic insulating film 181. The first power line VDL1 may be covered by the third planarization film 190.

The first power line VDL1 may overlap the first gap G1 in the third direction DR3. Therefore, the light traveling in the downward direction of the display panel 100 through the first gap GP1 from among the light emitted from the light emitting element EL disposed on the first pad electrode APD and the second pad electrode CPD may be blocked by the first power line VDL1.

A spaced portion SU between the first pad light blocking pattern BP1 and the second pad light blocking pattern BP2 may overlap the first gap GP1, but the first power line VDL1 may overlap the spaced portion SU between the first pad light blocking pattern BP1 and the second pad light blocking pattern BP2. Therefore, even though the spaced portion SU exists between the first pad light blocking pattern BP1 and the second pad light blocking pattern BP2, the light traveling in the downward direction of the display panel 100 through the first gap GP1 from among the light emitted from the light emitting element EL disposed on the first pad electrode APD and the second pad electrode CPD may be blocked by the first power line VDL1.

It has been illustrated in FIGS. 12-14 that the first pad light blocking pattern BP1 and the second pad light blocking pattern BP2 are included in the second gate metal layer because there is no second gate metal layer overlapping the first pad electrode APD and the second pad electrode CPD in the third direction DR3, but the present disclosure is not limited thereto. For example, when there is no first gate metal layer overlapping the first pad electrode APD and the second pad electrode CPD in the third direction DR3, the first pad light blocking pattern BP1 and the second pad light blocking pattern BP2 may be included in the first gate metal layer including the gate electrode G17 of the seventeenth transistor T17. Alternatively, when there is no first source metal layer overlapping the first pad electrode APD and the second pad electrode CPD in the third direction DR3, the first pad light blocking pattern BP1 and the second pad light blocking pattern BP2 may be disposed at the first source metal layer including the first connection electrode CCE1.

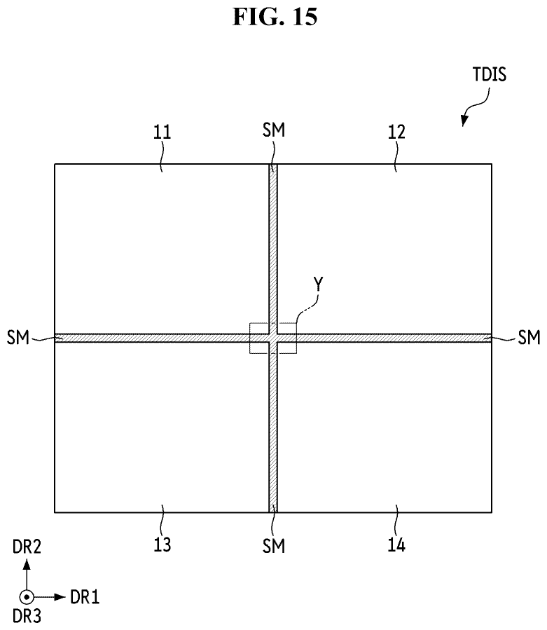

FIG. 15 is a perspective view illustrating a tiled display device including a plurality of display devices according to one or more embodiments.

Referring to FIG. 15, a tiled display device TDIS may include a plurality of display devices 11, 12, 13, and 14 and a seam portion SM. The plurality of display devices 11, 12, 13, and 14 may be arranged in a matrix form in M (M is a positive integer) rows and N (N is a positive integer) columns. For example, the tiled display device TDIS may include a first display device 11, a second display device 12, a third display device 13, and a fourth display device 14.

The first display device 11 and the second display device 12 may neighbor to each other in the first direction DR1. The first display device 11 and the third display device 13 may neighbor to each other in the second direction DR2. The third display device 13 and the fourth display device 14 may neighbor to each other in the first direction DR1. The second display device 12 and the fourth display device 14 may neighbor to each other in the second direction DR2.

However, the number and an arrangement of display devices 11, 12, 13, and 14 in the tiled display device TDIS are not limited to those illustrated in FIG. 15. The number and an arrangement of display devices 11, 12, 13, and 14 in the tiled display device TDIS may be determined according to sizes of each of the display device 10 and the tiled display device TDIS and a shape of the tiled display device TDIS.

The plurality of display devices 11, 12, 13, and 14 may have the same size, the present disclosure is not limited thereto. For example, the plurality of display devices 11, 12, 13, and 14 may have different sizes.

Each of the plurality of display devices 11, 12, 13, and 14 may have a rectangular shape having long sides and short sides. The plurality of display devices 11, 12, 13, and 14 may be disposed with long sides or short sides connected to each other. Some or all of the plurality of display devices 11, 12, 13, and 14 may be disposed at edges of the tiled display device TDIS and form one side of the tiled display device TDIS. At least one of the plurality of display devices 11, 12, 13, and 14 may be disposed at at least one corner of the tiled display device TDIS, and may form two adjacent sides of the tiled display device TDIS. At least one of the plurality of display devices 11, 12, 13, and 14 may be surrounded by the other display devices.

Each of the plurality of display devices 11, 12, 13, and 14 may be substantially the same as the display device 10 described with reference to FIG. 1. Therefore, a description of each of the plurality of display devices 11, 12, 13, and 14 is omitted.

The seam portion SM may include a coupling member or an adhesive member. In this case, the plurality of display devices 11, 12, 13, and 14 may be connected to each other through the coupling member or the adhesive member of the seam portion SM. The seam portion SM may be disposed between the first display device 11 and the second display device 12, between the first display device 11 and the third display device 13, between the second display device 12 and the fourth display device 14, and between the third display device 13 and the fourth display device 14.

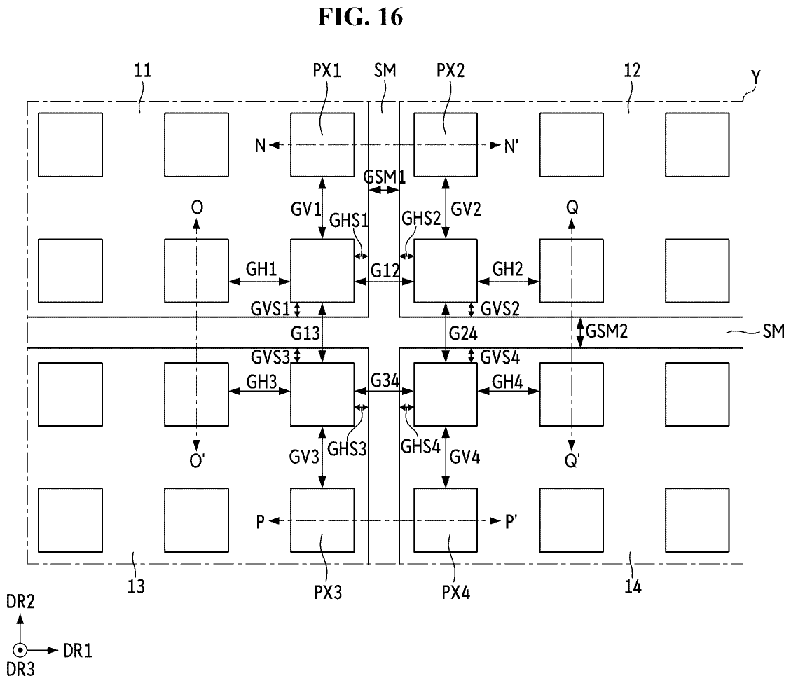

FIG. 16 is an enlarged layout diagram illustrating area Y of FIG. 15 in detail.

Referring to FIG. 16, the seam portion SM may have a cross shape or a plus sign (+) shape in a plan view in a central area of the tiled display device TDIS where the first display device 11, the second display device 12, the third display device 13, and the fourth display device 14 are adjacent to each other. The seam portion SM may be disposed between the first display device 11 and the second display device 12, between the first display device 11 and the third display device 13, between the second display device 12 and the fourth display device 14, and between the third display device 13 and the fourth display device 14.

The first display device 11 may include first pixels PX1 arranged in a matrix form in the first direction DR1 and the second direction DR2 in order to display an image. The second display device 12 may include second pixels PX2 arranged in a matrix form in the first direction DR1 and the second direction DR2 in order to display an image. The third display device 13 may include third pixels PX3 arranged in a matrix form in the first direction DR1 and the second direction DR2 in order to display an image. The fourth display device 14 may include fourth pixels PX4 arranged in a matrix form in the first direction DR1 and the second direction DR2 in order to display an image.

A minimum distance between the first pixels PX1 neighboring to each other in the first direction DR1 may be defined as a first horizontal spaced distance GH1, and a minimum distance between the second pixels PX2 neighboring to each other in the first direction DR1 may be defined as a second horizontal spaced distance GH2. The first horizontal spaced distance GH1 and the second horizontal spaced distance GH2 may be substantially the same as each other.

The seam portion SM may be disposed between the first pixel PX1 and the second pixel PX2 neighboring to each other in the first direction DR1. A minimum distance G12 between the first pixel PX1 and the second pixel PX2 neighboring to each other in the first direction DR1 may be the sum of a minimum distance GHS1 between the first pixel PX1 and the seam portion SM in the first direction DR1, a minimum distance GHS2 between the second pixel PX2 and the seam portion SM in the first direction DR1, and a width GSM1 of the seam portion SM in the first direction DR1.

The minimum distance G12 between the first pixel PX1 and the second pixel PX2 neighboring to each other in the first direction DR1, the first horizontal spaced distance GH1, and the second horizontal spaced distance GH2 may be substantially the same as each other. To this end, the minimum distance GHS1 between the first pixel PX1 and the seam portion SM in the first direction DR1 may be smaller than the first horizontal spaced distance GH1, and the minimum distance GHS2 between the second pixel PX2 and the seam portion SM in the first direction DR1 may be smaller than the second horizontal spaced distance GH2. In addition, the width GSM1 of the seam portion SM in the first direction DR1 may be smaller than the first horizontal spaced distance GH1 or the second horizontal spaced distance GH2.

A minimum distance between the third pixels PX3 neighboring to each other in the first direction DR1 may be defined as a third horizontal spaced distance GH3, and a minimum distance between the fourth pixels PX4 neighboring to each other in the first direction DR1 may be defined as a fourth horizontal spaced distance GH4. The third horizontal spaced distance GH3 and the fourth horizontal spaced distance GH4 may be substantially the same as each other.

The seam portion SM may be disposed between the third pixel PX3 and the fourth pixel PX4 neighboring to each other in the first direction DR1. A minimum distance G34 between the third pixel PX3 and the fourth pixel PX4 neighboring to each other in the first direction DR1 may be the sum of a minimum distance GHS3 between the third pixel PX3 and the seam portion SM in the first direction DR1, a minimum distance GHS4 between the fourth pixel PX4 and the seam portion SM in the first direction DR1, and the width GSM1 of the seam portion SM in the first direction DR1.

The minimum distance G34 between the third pixel PX3 and the fourth pixel PX4 neighboring to each other in the first direction DR1, the third horizontal spaced distance GH3, and the fourth horizontal spaced distance GH4 may be substantially the same as each other. To this end, the minimum distance GHS3 between the third pixel PX3 and the seam portion SM in the first direction DR1 may be smaller than the third horizontal spaced distance GH3, and the minimum distance GHS4 between the fourth pixel PX4 and the seam portion SM in the first direction DR1 may be smaller than the fourth horizontal spaced distance GH4. In addition, the width GSM1 of the seam portion SM in the first direction DR1 may be smaller than the third horizontal spaced distance GH3 or the fourth horizontal spaced distance GH4.

A minimum distance between the first pixels PX1 neighboring to each other in the second direction DR2 may be defined as a first vertical spaced distance GV1, and a minimum distance between the third pixels PX3 neighboring to each other in the second direction DR2 may be defined as a third vertical spaced distance GV3. The first vertical spaced distance GV1 and the third vertical spaced distance GV3 may be substantially the same as each other.

The seam portion SM may be disposed between the first pixel PX1 and the third pixel PX3 neighboring to each other in the second direction DR2. A minimum distance G13 between the first pixel PX1 and the third pixel PX3 neighboring to each other in the second direction DR2 may be the sum of a minimum distance GVS1 between the first pixel PX1 and the seam portion SM in the second direction DR2, a minimum distance GVS3 between the third pixel PX3 and the seam portion SM in the second direction DR2, and a width GSM2 of the seam portion SM in the second direction DR2.

The minimum distance G13 between the first pixel PX1 and the third pixel PX3 neighboring to each other in the second direction DR2, the first vertical spaced distance GV1, and the third vertical spaced distance GV3 may be substantially the same as each other. To this end, the minimum distance GVS1 between the first pixel PX1 and the seam portion SM in the second direction DR2 may be smaller than the first vertical spaced distance GV1, and the minimum distance GVS3 between the third pixel PX3 and the seam portion SM in the second direction DR2 may be smaller than the third vertical spaced distance GV3. In addition, the width GSM2 of the seam portion SM in the second direction DR2 may be smaller than the first vertical spaced distance GV1 or the third vertical spaced distance GV3.

A minimum distance between the second pixels PX2 neighboring to each other in the second direction DR2 may be defined as a second vertical spaced distance GV2, and a minimum distance between the fourth pixels PX4 neighboring to each other in the second direction DR2 may be defined as a fourth vertical spaced distance GV4. The second vertical spaced distance GV2 and the fourth vertical spaced distance GV4 may be substantially the same as each other.

The seam portion SM may be disposed between the second pixel PX2 and the fourth pixel PX4 neighboring to each other in the second direction DR2. A minimum distance G24 between the second pixel PX2 and the fourth pixel PX4 neighboring to each other in the second direction DR2 may be the sum of a minimum distance GVS2 between the second pixel PX2 and the seam portion SM in the second direction DR2, a minimum distance GVS4 between the fourth pixel PX4 and the seam portion SM in the second direction DR2, and the width GSM2 of the seam portion SM in the second direction DR2.

The minimum distance G24 between the second pixel PX2 and the fourth pixel PX4 neighboring to each other in the second direction DR2, the second vertical spaced distance GV2, and the fourth vertical spaced distance GV4 may be substantially the same as each other. To this end, the minimum distance GVS2 between the second pixel PX2 and the seam portion SM in the second direction DR2 may be smaller than the second vertical spaced distance GV2, and the minimum distance GVS4 between the fourth pixel PX4 and the seam portion SM in the second direction DR2 may be smaller than the fourth vertical spaced distance GV4. In addition, the width GSM2 of the seam portion SM in the second direction DR2 may be smaller than the second vertical spaced distance GV2 or the fourth vertical spaced distance GV4.

As illustrated in FIG. 16, in order to prevent the seam portion SM from being viewed between images displayed by the plurality of display devices 11, 12, 13, and 14, a minimum distance between pixels of the display devices neighboring to each other may be substantially the same as a minimum distance between pixels of each of the display devices.

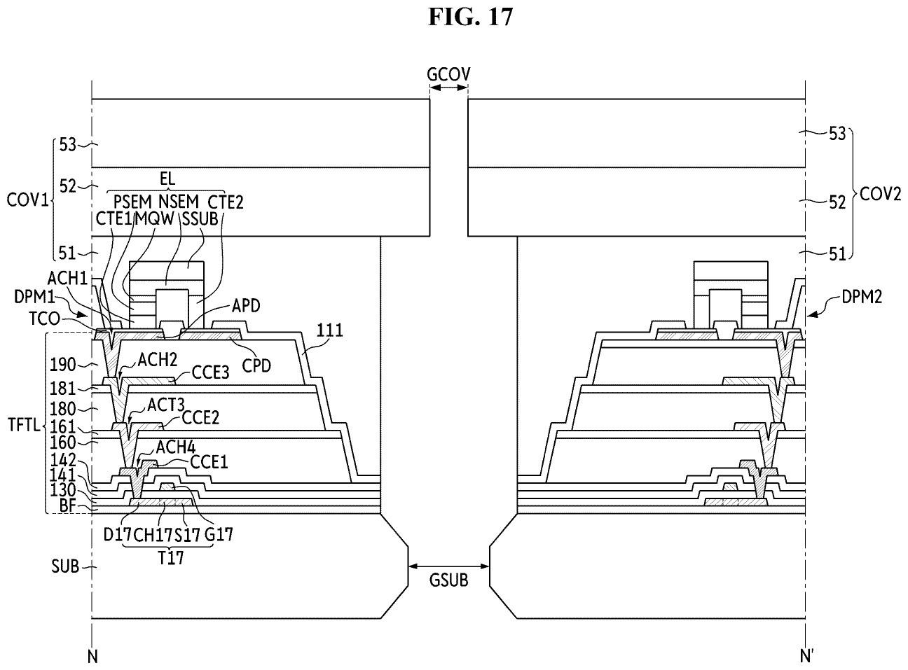

FIG. 17 is a cross-sectional view illustrating an example of the tiled display device taken along the line N-N′ of FIG. 16.

Referring to FIG. 17, the first display device 11 includes a first display module DPM1 and a first front cover COV1. The second display device 12 includes a second display module DPM2 and a second front cover COV2.

Each of the first display module DPM1 and the second display module DPM2 includes a substrate SUB, a thin film transistor T17, and a light emitting element EL. The substrate SUB, the thin film transistor T17, and the light emitting element EL illustrated in FIG. 17 are substantially the same as the substrate SUB, the thin film transistor T17, and the light emitting element EL described with reference to FIG. 7, and a description thereof is thus omitted.

A distance GSUB between the substrate SUB of the first display device 11 and the substrate SUB of the second display device 12 may be greater than a distance GCOV between the first front cover COV1 and the second front cover COV2.

Each of the first front cover COV1 and the second front cover COV2 may include an adhesive member 51, a light transmissivity adjusting layer 52 disposed on the adhesive member 51, and an anti-glare layer 53 disposed on the light transmissivity adjusting layer 52.

The adhesive member 51 of the first front cover COV1 serves to adhere a light emitting element layer EML1 of the first display module DPM1 and the first front cover COV1 to each other. The adhesive member 51 of the second front cover COV2 serves to adhere a light emitting element layer EML2 of the second display module DPM2 and the second front cover COV2 to each other. The adhesive member 51 may be a transparent adhesive member capable of transmitting light. For example, the adhesive member 51 may be an optically clear adhesive film or an optically clear resin.

The anti-glare layer 53 may be designed to diffusely reflect external light in order to prevent deterioration of visibility of an image occurring because the external light is reflected as it is. Accordingly, a contrast ratio of images displayed by the first display device 10 and the second display device 20 may be increased due to the anti-glare layer 53.

The light transmissivity adjusting layer 52 may be designed to reduce transmissivity of external light or light reflected from the first display module DPM1 and the second display module DPM2. For this reason, the distance GSUB between the substrate 100 of the first display module DPM1 and the substrate 100 of the second display module DPM2 may be prevented from being viewed from the outside.

The anti-glare layer 53 may be implemented as a polarizing plate, and the light transmissivity adjusting layer 52 may be implemented as a phase delay layer, but the present disclosure is not limited thereto.

An example of the tiled display device taken along the line O-O′, the line P-P′, and the line Q-Q′ of FIG. 16 is substantially the same as an example of the tiled display device taken along the line N-N′ described with reference to FIG. 17, and a description thereof is thus omitted.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
a first pad electrode on the substrate;
a second pad electrode spaced from the first pad electrode on the substrate;
a light emitting element comprising a first electrode connected to the first pad electrode and a second electrode connected to the second pad electrode;
a first power line spaced from the first pad electrode on the substrate, connected to a first side of the second pad electrode, and configured to receive a first source voltage; and
a pad light blocking pattern overlapping a first gap between the first pad electrode and the first power line and a second gap between the second pad electrode and the first power line.

2. The display device of claim 1, further comprising a second power line overlapping a third gap between the first pad electrode and the second pad electrode and configured to receive a second source voltage.

3. The display device of claim 1, further comprising a lower light blocking pattern overlapping the pad light blocking pattern in a thickness direction of the substrate.

4. The display device of claim 3, wherein an area of the lower light blocking pattern is greater than an area of the pad light blocking pattern.

5. The display device of claim 3, wherein a thickness of the lower light blocking pattern is smaller than a thickness of the pad light blocking pattern.

6. The display device of claim 1, wherein the pad light blocking pattern comprises:
a first pad light blocking pattern overlapping the first gap; and
a second pad light blocking pattern overlapping the second gap and spaced apart from the first pad light blocking pattern.

7. The display device of claim 6, further comprising a second power line configured to receive a second source voltage.

8. The display device of claim 7, wherein the second power line overlaps a third gap between the first pad electrode and the second pad electrode.

9. The display device of claim 7, wherein a minimum distance between the first pad light blocking pattern and the second pad light blocking pattern in one direction is greater than a length of the third gap in the one direction.

10. The display device of claim 1, wherein the first pad electrode, the second pad electrode, and the first power line comprise a same material.

11. The display device of claim 1, wherein the second pad electrode and the first power line are formed integrally with each other.

12. A display device comprising:
a substrate;
a first pad electrode on the substrate;
a second pad electrode spaced from the first pad electrode on the substrate;
a light emitting element comprising a first electrode connected to the first pad electrode and a second electrode connected to the second pad electrode;
a first power line spaced from the first pad electrode on the substrate, connected to a first side of the second pad electrode, and configured to receive a first source voltage; and
a lower light blocking pattern overlapping a first gap between the first pad electrode and the first power line and a second gap between the second pad electrode and the first power line.

13. The display device of claim 12, wherein a thickness of the lower light blocking pattern is 3,000 Å or more.

14. The display device of claim 12, further comprising:
an active layer of a thin film transistor on the substrate;
a first insulating film on the active layer of the thin film transistor;
a gate electrode of the thin film transistor on the first insulating film and overlapping the active layer of the thin film transistor in a thickness direction of the substrate; and
a second insulating film on the gate electrode of the thin film transistor.

15. The display device of claim 14, wherein the lower light blocking pattern is on the substrate and the active layer of the thin film transistor, and
the display device further comprises a third insulating film between the lower light blocking pattern and the active layer of the thin film transistor.

16. The display device of claim 14, wherein the first pad electrode and the second pad electrode are on the second insulating film.

17. A tiled display device comprising:
a plurality of display devices; and
a seam portion between the plurality of display devices,
wherein a display device from among the plurality of display devices comprises
a substrate;
a first pad electrode on a first surface of the substrate;
a second pad electrode spaced from the first pad electrode on the substrate;
a light emitting element comprising a first electrode connected to the first pad electrode and a second electrode connected to the second pad electrode;
a first power line spaced apart from the first pad electrode on the substrate, connected to a first side of the second pad electrode, and configured to receive a first source voltage; and
a pad light blocking pattern overlapping a first gap between the first pad electrode and the first power line and a second gap between the second pad electrode and the first power line.

18. The tiled display device of claim 17, wherein the substrate comprises glass.

19. The tiled display device of claim 17, wherein the display device further comprises:
a side surface line on one side surface between the first surface of the substrate and a second surface opposite to the first surface;
a back surface line and a device identifier on the second surface of the substrate; and
a flexible film connected to the back surface line through a conductive adhesive member.

20. The tiled display device of claim 17, wherein the plurality of display devices are arranged in a matrix form along M rows and N columns.

21. An electronic device comprising a display device, the display device comprising:
a substrate;
a first pad electrode on the substrate;
a second pad electrode spaced from the first pad electrode on the substrate;
a light emitting element comprising a first electrode connected to the first pad electrode and a second electrode connected to the second pad electrode;
a first power line spaced from the first pad electrode on the substrate, connected to a first side of the second pad electrode, and configured to receive a first source voltage;
a pad light blocking pattern overlapping a first gap between the first pad electrode and the first power line and a second gap between the second pad electrode and the first power line; and
a lower light blocking pattern overlapping the pad light blocking pattern in a thickness direction of the substrate.

22. The electronic device of claim 1, wherein the electronic device comprises televisions, laptop computers, monitors, billboards, the Internet of Things (IOT) devices, mobile phones, smartphones, tablet personal computers (PCs), smart watches, watch phones, mobile communication terminals, electronic notebooks, electronic books, portable multimedia players (PMPs), navigation devices, or ultra mobile PCs (UMPCs).
